(19) United States
(12) Patent Application Publication
(10) Pub. No.: US 2023/0349987 A1
(43) Pub. Date: Nov. 2, 2023

(54) COMPARATIVE MEASUREMENT USING PARTICLES WITHIN ONE OR MORE COMPARTMENTS

(71) Applicant: Analog Devices International Unlimited Company, Limerick (IE)

(72) Inventors: Alan J. O’Donnell, Castletroy (IE); Shaun Bradley, Patrickswell (IE); Alfonso Berduque, Crusheen (IE); Jan Kubík, Limerick (IE); Jochen Schmitt, Biedenkopf (IE); Stanislav Jolondcovschi, Carlow (IE); Javier Calpe Maravilla, Algemesi (ES); Padraig L. Fitzgerald, Mallow (IE); Gavin Patrick Cosgrave, Enniscorthy (IE); Michael P. Lynch, Bruff (IE); Eoin Edward English, Pallasgreen (IE)

(21) Appl. No.: 18/299,627

(22) Filed: Apr. 12, 2023

Related U.S. Application Data
(60) Provisional application No. 63/363,885, filed on Apr. 29, 2022.

(51) Int. Cl. G01R 33/02; G01K 11/06

(52) U.S. Cl. CPC G01R 33/0213; G01K 11/06

(57) ABSTRACT

Aspects of this disclosure relate to generating measurements based on positions of particles within one or more compartments. At least some of the particles can move in response to an external stimulus. A comparative measurement can be provided based on comparing the measurements. The measurements can be associated with two or more types of particles and/or two or more compartments.

### CROSS REFERENCE TO PRIORITY APPLICATION

Any and all applications for which a foreign or domestic priority claim is identified in the Application Data Sheet as filed with the present application are hereby incorporated by reference under 37 C.F.R. §1.57. This application claims the benefit of priority of U.S. Provisional Application No. 63/363,885, filed Apr. 29, 2022 and titled “COMPARATIVE MEASUREMENT USING PARTICLES WITHIN ONE OR MORE COMPARTMENTS,” the disclosure of which is hereby incorporated by reference in its entirety and for all purposes.

### BACKGROUND

### Technical Field

The disclosed technology relates to sensing based on movement and/or location of particles within on or more compartments or enclosures.

### Description of Related Technology

Magnetic fields, bodies and/or other stimuli can be detected in a variety of applications. A system or apparatus sensing magnetic fields can be used for a variety of purposes. Certain magnetic field sensors are manufactured with semiconductor fabrication processes and some can also be constructed by adding additional layers post wafer fabrication or by attaching or depositing or bonding additional materials, structures or laminates/layers (incorporating magnetic materials) onto (or beside) semiconductors. Such magnetic field sensors can be packaged with other semiconductor circuitry, chiplets, etc. to construct functional packages, modules, or System in Packages (SIPs).

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a method that includes generating a first measurement and a second measurement based on positions of particles within one or more compartments. At least some of the particles move in response to an external stimulus. The method includes providing a comparative measurement based on comparing at least the first measurement with the second measurement. The first and second measurements are associated with two or more types of particles and/or two or more compartments.

The external stimulus can be a magnetic field, and the comparative measurement can be indicative of the magnetic field. The comparative measurement can be indicative of a temperature being within a temperature range. The comparative measurement can be indicative of a force applied to the one or more compartments.

In some instances, the plurality of compartments enables a range of values to be monitored. The difference in the compartment constructions can add granularity to the measurements and/or sensitivity to the system. One or more thresholds, alarms, and/or flags can be set based on monitoring the plurality of compartments.

The compartments can be located to enhance and/or maximize detection depending on specifications of a particular application. The compartments can be located orthogonally, radially, and/or areas to be monitored. Accordingly, the compartments can be intentionally arranged to generate a useful result.

In some instances, one enclosure can be divided into different compartments. Sensing structures can be incorporated into different areas of the one enclosure to compartmentalize the one enclosure into different areas.

The particles can be magnetically sensitive and in at least one fluid. The particles can be magnetically sensitive and embedded in at least one film. The particles can be in at least one magnetically sensitive fluid.

The first and second measurements can be associated with the two or more types of particles. The two or more types of particles have different magnetic sensitivities. The two or more types of particles have different sizes and/or shapes.

The method can include resetting the positions of particles before generating the first measurement.

The second measurement can be generated based on optical detection of the at least some of the particles after exposure to the external stimulus.

The first and second measurements can be associated with the two or more compartments. The two or more compartments can comprise different fluid channels. The two or more compartments can comprise different sealed enclosures. The particles can comprise different types of particles in different respective compartments of the two or more compartments. The different types of particles have different magnetic sensitivities. The different types of particles can have different sizes and/or shapes. The two or more compartments can comprise different medium materials in different respective compartments of the two or more compartments. The different medium materials can change viscosity in response to a change in temperature. The particles can be in different fluids in each of the two or more compartments.

The one or more compartments can include an integrated sensing structure. The one or more compartments can include an integrated magnetic structure configured to provide a bias. The one or more compartments can include an integrated conductive structure.

Another aspect of this disclosure is a method that includes generating a first measurement and a second measurement based on positions of magnetically sensitive particles within one or more compartments, and providing a comparative measurement based on comparing at least the first measurement with the second measurement. The first and second measurements are associated with two or more types of particles and/or two or more compartments.

Another aspect of this disclosure is a system that includes a first compartment containing one or more first particles, a second compartment containing one or more second particles, and a measurement circuit configured to generate a measurement based on comparing a first measurement associated with position of the one or more first particles and a second measurement associated with position of the one or more second particles. The one or more first particles are configured to move in response to an external stimulus.

The external stimulus can be a magnetic field, and the measurement can be indicative of the magnetic field. The measurement can be indicative of a temperature being within a temperature range.

The one or more first particles can be in a first fluid and the one or more second particles can be in a second fluid. The first fluid can be a different type of fluid than the second fluid. The one or more first particles can have a different mobility in the first fluid than the one or more second particles have in the second fluid at a particular temperature.

The one or more first particles and one or more the second particles can have different magnetic sensitivities. The one or more first particles and the one or more second particles can have different sizes and/or shapes.

Another aspect of this disclosure is a system that includes a compartment containing at least two types of particles, and a measurement circuit configured to generate a measurement based on comparing a first measurement and a second measurement. The first measurement is associated with positions of the at least two types of particles. The second measurement is associated with positions of at least some particles of the at least two types of particles moving in response to an external stimulus relative to the positions associated with the first measurement.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will be described, by way of non-limiting example, with reference to the accompanying drawings.

FIGS. 1A, 1B, and 1C are schematic side or cross-sectional views of a container or enclosure that includes magnetically sensitive particles in a fluid according to an embodiment.

FIGS. 2A and 2B are schematic side or cross-sectional views of a container or enclosure that includes non-magnetically sensitive particles in a ferromagnetic fluid according to an embodiment.

FIGS. 3A and 3B are schematic side or cross-sectional views of a container or enclosure that includes a film with magnetically sensitive particles according to an embodiment in two different states.

FIGS. 3C, 3D, 3E, and 3F schematically illustrate examples of a film with embedded magnetically sensitive particles within a container or enclosure in plan view according to embodiments.

FIGS. 4A, 4B, 4C, 4D, and 4E are schematic side or cross-sectional views of example containers or enclosures with various cross-sectional shapes according to embodiments.

FIGS. 4F, 4G, and 4H illustrate schematic plan views of a container or enclosure with a constricted region according to an embodiment.

FIG. 5A is a schematic cross-sectional view of an example enclosure having a plurality of integrated structures according to an embodiment.

FIG. 5B is a schematic isometric view of an example container with an integrated heating element according to an embodiment.

FIG. 5C is a schematic isometric view of an example container with an integrated piezoelectric element according to an embodiment.

FIG. 5D is a schematic side or cross-sectional view of an example container or enclosure enclosing a film with embedded particles, where the container has flexible surface according to an embodiment.

FIGS. 5E and 5F are schematic cross-sectional and corresponding plan views of example enclosures incorporating patterned structures according to embodiments.

FIGS. 5G and 5H are schematic plan views of an example enclosure with a magnetically sensitive particle in phase change material according to an embodiment.

FIG. 6A illustrates example shapes of magnetically sensitive particles. FIG. 6B illustrates example combined structures with magnetically sensitive particles included within non-magnetic material. FIG. 6C shows examples of clusters of particles.

FIG. 7 is a schematic block diagram of a magnetic field sensing system according to an embodiment.

FIGS. 8A, 8B, 8C, 8D, and 8E are schematic cross sections of systems in a package with a container that includes particles that move in response to an applied magnetic field according to embodiments.

FIG. 9 is a schematic cross section of a system in a package with a container that includes particles that move in response to an applied magnetic field, where the container is encapsulated in a laminate according to an embodiment.

FIGS. 10A and 10B schematically illustrate example integrated systems with enclosures containing magnetically sensitive particles according to embodiments

FIG. 11 illustrates an exploded schematic view of an example magnetic field measurement system with wireless communication according to an embodiment.

FIG. 12 is a schematic isometric view of a photonic module that includes an enclosure with particles that move in response to an applied magnetic field according to an embodiment.

FIG. 13 is a schematic isometric view of an electronic module with electronic elements and an enclosure with particles that move in response to an applied magnetic field according to an embodiment.

FIGS. 14A, 14B, and 14C are schematic side or cross-sectional views of an example system for detecting a magnetic field based on case conductance according to an embodiment.

FIGS. 15A, 15B, and 15C are schematic side or cross-sectional views of a system for detecting magnetic field intensity with case conductance measurement according to an embodiment.

FIGS. 16A, 16B, 16C, 16D, 16E, and 16F are schematic side or cross-sectional views of enclosures with magnetically sensitive particles for zero-power magnetic field detection according to an embodiment.

FIGS. 17A and 17B are schematic side or cross-sectional views of a system configured for cumulative magnetic field exposure detection according to an embodiment.

FIGS. 18, 19, and 20 illustrate example microelectromechanical systems structures interacting with magnetically sensitive particles within a container according to embodiments.

FIGS. 21A and 21B are schematic side or cross-sectional views of a container with magnetically sensitive particles in a phase change material, wherein the container has integrated magnetic sensors according to an embodiment.

FIG. 22A is a schematic cross section of a container with magnetically sensitive particles with optical detection according to an embodiment.

FIG. 22B is a schematic cross section of a container with magnetically sensitive particles with optical detection according to another embodiment.

FIGS. 23A and 23B are schematic cross sectional or side views of optical measurement systems according to embodiments. FIG. 23C is a schematic view of a portion of the optical systems of FIGS. 23A and 23B.

FIG. 24 illustrates schematic side and plan views of a system with one-dimensional capacitive sensing of particles within a container according to an embodiment.

FIG. 25 illustrates schematic side and plan views of a system with two-dimensional capacitive sensing of particles within a container according to another embodiment.

FIG. 26 illustrates a plan view of a system with a plurality of compartments or enclosures that include particles according to an embodiment.

FIG. 27A is an isometric view of a system with a plurality of compartments or enclosures, each including particles according to an embodiment. FIG. 27B is a plan view of the system of FIG. 27A that illustrates areas of the compartments.

FIGS. 28A to 28E illustrate examples of compartments or enclosures and integrated structures according to embodiments.

FIG. 29 illustrates an array of compartments or enclosures that each include particles according to an embodiment.

FIG. 30 illustrates a plurality of containers or enclosures with particles in different respective medium materials according to an embodiment.

FIG. 31 illustrates a system that includes plurality of compartments or enclosures with respective particles having different sizes according to an embodiment.

FIGS. 32A to 32E illustrate example fluid channels or enclosures with magnetically sensitive particles according to embodiments.

FIGS. 33A and 33B illustrate a fluid channel with different types of particles according to an embodiment.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings. The headings provided herein are for convenience only and do not necessarily affect the scope or meaning of the claims.

Aspects of this disclosure relate to detecting a magnetic field based on position and/or movement of at least one particle within a container or enclosure. Particles can be included in a container or enclosure that retains the particles or constrains their movement within a desired area or path. The particles move within the container in response to an applied magnetic field. The container can be a sealed enclosure. The particles can be magnetically sensitive particles in a fluid, magnetically sensitive particles embedded in a film, or particles (for example, non-magnetically sensitive particles) in a ferromagnetic fluid or gel. Whether the particles themselves respond directly to the magnetic field, or whether they move because the fluid or film within which they are held responds directly to the magnetic field, the particles are capable of moving within the container or enclosure in response to an applied magnetic field and/or another stimulus. The response of the material within the container or enclosure to a magnetic stimulus can produce a response with a discernible signature that can be measured to give an indication of one or more of the strength, direction, intensity, position, shape, or another property of a magnetic body or field - depending on the specification of a particular application. For example, a measurement circuit can measure the applied magnetic field based on position of the particles. A measurement circuit can measure the applied magnetic field based on movement of the particles. At least part of the measurement circuit can be included in an integrated circuit that is integrated with the container. The container and the measurement circuit can be included in a system in a package that includes a packaging structure enclosing the measurement circuit. The packaging structure can include an opening where at least a portion of the container is exposed by the opening. The system can be constructed such that the enclosure is positioned sufficiently close to the surface of the package (or module) so that the enclosure is still physically protected and the sensitive materials within the enclosure are capable of detecting magnetic fields close to the package surface. The magnetic field detection described herein has a variety of applications, such as detection of bodies with magnetic fields, biological sensing, position sensing, proximity sensing, force/impact sensing and current sensing, among others.

In certain embodiments, particles in a sealed enclosure can move in response to an applied magnetic field. The applied magnetic field can be any magnetic field applied to an enclosure. In certain applications, the applied magnetic field is an external magnetic field applied to a magnetic field measurement system. A measurement circuit can detect the applied magnetic field based on positions or movement of the particles or fluid or gel. Some or all of the circuitry of the measurement circuit can be included in an integrated circuit that is integrated with the enclosure. A sensor can sense the particles and provide an output signal to the measurement circuit in certain applications. A variety of different measurement techniques can be used to detect the particles, such as capacitive sensing, detecting an electrical short, magnetic sensing, optical sensing, microelectromechanical systems based sensing, or the like depending on the specification of a particular application. In some instances, a relaxation process after switching off a magnetic field can be sensed. A frequency dependent response can be sensed in an alternating current field in some applications.

The particles can have properties that facilitate movement and/or interactions with one another (e.g., clustering behavior, interlocking mechanisms, materials that attract or repel [e.g., paramagnetic or diamagnetic materials]) or within the enclosure itself in response to an applied magnetic field. Examples of such properties can include one or more of shape, material, size, density, weight, surface area, surface patterning, or the like. The particles can be suspended or embedded within a fluid, a gel, or a material that in combination the particles can respond in a desired way to a magnetic field depending on the specifications of a particular application.

The enclosure can include a conductive material in certain applications. The enclosure can include non-conductive materials in some applications. One or more magnetic structures can be integrated with the enclosure to modify and/or generate a magnetic field applied to the particles. A system can be configured such that the enclosure interacts with an external magnetic stimulus. The enclosure can contain conductive patterns and have areas within designed to detect the presence and/or clustering of magnetic or non-magnetic particles within the enclosure or within specific areas or locations of the enclosure. The container can include one or more conductive vias from the internal surface to the external surfaces. Alternatively or additionally, the container can include one or more optical conduits and/or areas within the container that facilitate optical detection of particle clusters or movement of particles within certain areas or locations within the enclosure.

Embodiments disclosed herein can achieve advantages over other methods of magnetic field detection. For example, there can be advantages related to manufacturing. A container with particles can be manufactured separately from electronics, such as a measurement circuit, in a non-semiconductor process. As another example, parts of systems disclosed herein can be configured for magnetic field detection in environments that are not typically suitable for semiconductor components. Enclosing particles in a container of certain materials (for example, glass or metallic or a laminate/composite structure or ceramic) can enable at least part of the system to be exposed to a harsher environment (e.g., temperatures >100° C.-150° C. and/or environments containing harsh chemicals such as acids) than typically used standard packaged semiconductor circuitry.

An advantage of embodiments disclosed herein is that omnidirectional magnetic field detectors can be implemented efficiently in accordance with principles and advantages disclosed herein. By contrast, most magnetic field detectors measure magnetic fields in a given direction, such that in order to detect fields in multiple directions, sensing structures are replicated at greater cost, space occupancy and complexity.

Another advantage of embodiments disclosed herein is ease of modifying the sensitivity and/or range of magnetic field detection by changing one or more features of the particles (e.g., nature, size, shape, construction or number of particles), one or more features of the fluid in which the particles are immersed, or one or more features of the enclosure (e.g., by adding one or more shields or thinning the enclosure or incorporating a specific shape or indentation or material or feature such as sensor or patterned or conductive material or optical window). Also, it is relatively easy to adjust the sensitivity curve. This can allow magnetic field detection that can be made particularly sensitive to a certain range of field intensities, allowing for sensitivity to lower intensity fields and avoiding saturation in more intense fields, as desired depending on the specific requirements of the application.

Structures disclosed herein can also facilitate detection without power. Particles can cluster in or within a container in response to a magnetic field. The particles can move and adopt positions in response to external fields while no power is applied to the detector. Power can be subsequently applied for interrogation, such as detecting and measuring positions or change in positions of particles or clusters of the particles. The physical construction or shape of the container can facilitate the detection or measurement of particle position. The detected positions can reflect cumulative and/or time related exposure to a magnetic field. Such detectors can be passive systems attached as a label to an element to track exposure to magnetic fields over time. A measurement circuit can read out a maximum field intensity that the device has been exposed to or another magnetic field measurement. Resetting magnetic field detectors can be relatively easy.

Certain geometries can be created in accordance with principles and advantages disclosed herein to create systems that are sensitive to certain patterns in a magnetic field. These can be constructed depending on the specifications of a particular application. For example, if there is a rotational field, whether the rotation changes its characteristics can be detected. As another example, a type of security lock can be implemented where applying a certain pattern of a dynamic magnetic field can open a lock.

Optical detectors and/or emitters can be used instead of a magnetic field sensor to sense the movement, shape and/or position of the particles. Optical detection can result in a faster response time in certain applications.

A reed switch type detector can be implemented. The reed switch detector can generate a contact when a magnetic field is applied and open when the magnetic field falls under a certain limit. A contact can be generated that is still closed (or still open) after applying the field. This can involve two electrodes in a container and particles closing the contact.

Aspects of this disclosure relate to generating a comparative measurement based on multiple measurements associated with particles in one or more compartments or enclosures. The particles can move in response to an external stimulus, such as an applied magnetic field or an applied force. The particles can be magnetically sensitive in certain applications. The multiple measurements can be associated with different types of particles and/or different compartments or enclosures. In some instances, different compartments include different respective types of particles, such as particles with different sizes, masses, densities, shapes, sensitivities to an external stimulus, the like, or any suitable combination thereof. Alternatively or additionally, particles in different compartments can be in different fluids or gels. In the different fluids, particles can have different mobilities (e.g., different viscosities, elasticities, etc.). Combining measured responses from different enclosures may enable a desirable system measurement sensitivity to an external targeted stimulus. In some applications, the multiple measurements can be associated with a plurality of types of particles within a single compartment or enclosure. The one or more compartments can include sealed enclosure(s), fluid channels, different fluid or gels, different particle sizes or shapes, or the like.

Measurement sensitivity can be increased by the multiple measurements associated with different particles and/or compartments or enclosures. For example, with different types of particles in different compartments, each compartment can detect if a parameter (e.g., magnetic field, temperature, or force) is above or below a respective threshold value. With multiple compartments, the parameter can be determined within a range between thresholds associated with different compartments. Such a range is more accurate than detecting that the parameter is either below or above a threshold value. As another example, different types of particles with different respective sensitivities to an external stimulus can enable finer detection of an external stimulus based on the movement of the different types of particles.

With multiple compartments including particles, the presence and/or movement of an external stimulus (e.g., a magnetic field) can be localized. For example, sensing particle movement in a particular compartment (or area within a compartment) and not other compartments can indicate a location (or relative location, direction, intensity, etc.) of the external stimulus.

Comparative measurement embodiments can be implemented in accordance with any suitable measurement techniques disclosed herein. Accordingly, the comparative measurement embodiments can achieve advantages related to measurements associated with movement and/or location of particles in a container together with increased accuracy, sensitivity, and/or localization

Combining more than one compartment or enclosure can improve the sensitivity of the system. A plurality of enclosures can enable comparative measurements, making the system more robust against environmental conditions that might affect the accuracy if there were only one enclosure and no comparative measurement. Depending on the application specifications, embodiments can include one or more of different material and/or fluid or gel properties within the enclosures (enabling the particles/sensitive material embedded within to move in different ways), different sized particles, different shaped particles, or particles with different sensitive layers or materials constructed with different thicknesses or patterns. A plurality of enclosures with combinations (as desired) of features described herein can accomplish at least one of the following: affect the sensitivity of the system, system response time, contribute to defining a threshold for a system response, or target detection of larger bodies moving in specific paths or directions or proximity to the system sensing elements.

### Magnetically Sensitive Particles in Fluid

Embodiments disclosed herein relate to a container with magnetically sensitive particles in a fluid. The magnetically sensitive particles can be retained within the container. The container can be a sealed enclosure. The magnetically sensitive particles and possibly the fluid also can be selected such that the magnetically sensitive particles can move within the container in response to exposure to an applied magnetic field in a detectable manner. The fluid can be a liquid or a gel having a viscosity suitable to facilitate movement of the magnetically sensitive particles within the container such that the movement of the particles can be detected. The fluid can have a suitable density and viscosity based on a desired range of measurement for a particular application. The fluid can have a dilation constant that is relatively small such that there are no significant technical challenges with forcing the enclosure when temperature drifts. Example fluids include without limitation aqueous solutions (e.g., buffers, aqueous electrolytes, aqueous solutions with conductive salts, aqueous solutions without conductive salts, pH buffers, salts in water, etc.), organic solutions (e.g., oils or organic solvents), aqueous or organic gels (e.g., a hydrogel, PVC, polyacrylic acid, a polyvinyl-alcohol gel, a polydimethylsiloxane gel, agarose-PBS, a PVC gel in organic solvents such as 2-nitrophenyl octyl ether, etc.), a wax, a conductive polymer (e.g., PEDOT, Nafion dispersions, etc.), water, an alcohol, an oil, or a fluid that allows Brownian motion of magnetically sensitive particles within the fluid. Positions of the magnetically sensitive particles can be detected optically, with capacitive sensing, by determining an electrical short, with magnetic sensing, or the like.

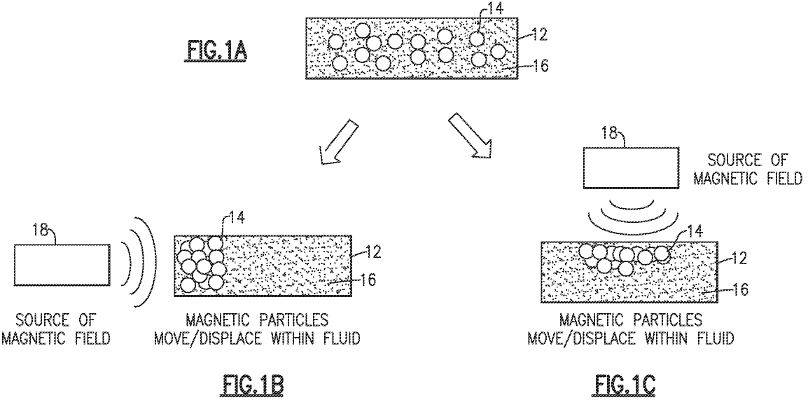

FIGS. 1A, 1B, and 1C illustrate a container 12 that includes magnetically sensitive particles 14 in a fluid 16 according to an embodiment. The container 12 can be a sealed enclosure. The magnetically sensitive particles 14 can include any suitable combination of features of the magnetically sensitive particles disclosed herein. The magnetically sensitive particles 14 can include one or more of the following materials: iron, cobalt, nickel, graphite, chromium, or any suitable alloy thereof. The magnetically sensitive particles 14 can include one or more of the following materials: Heusler alloys or chromium oxide. In certain applications, magnetically sensitive particles 14 can include polystyrene (PS) magnetic particles. Polystyrene magnetic particles can be synthesized by embedding superparamagnetic iron oxide into polystyrene. Polystyrene magnetic particles can be positively charged (e.g., by amine modification), unmodified, or negatively changed (e.g., by carboxyl modification). In some applications, magnetically sensitive particles can include streptavidin coated magnetic particles. FIG. 1A illustrates a position of the magnetically sensitive particles 14 when no external magnetic field is being applied.

A magnetic field source 18 can apply a magnetic field to move the magnetically sensitive particles 14 within the fluid 16. In some instances, the magnetic field source 18 can be a magnetic body. The magnetic field source 18 can include alternating poles. This can enhance attraction of magnetically sensitive particles 14 in certain applications. The applied magnetic field can be a gradient magnetic field to move the magnetically sensitive particles 14. A homogenous magnetic field can cause the magnetically sensitive particles 14 to attract each other and cluster. In some instances, clustering of the mangetically sensitive particles 14 can be detected.

FIG. 1B illustrates that a magnetic field can move the magnetically sensitive particles 14 to a side of the container 12. FIG. 1C illustrates that a different magnetic field can move the magnetically sensitive particles 14 in a different direction. In FIGS. 1A, 1B, and 1C, the magnetically sensitive particles 14 are attracted to the applied magnetic field. The magnetically sensitive particles 14 can be paramagnetic, for example. Paramagnetic materials include metals that are weakly attracted to magnets. Examples of paramagnetic materials include lithium, aluminium, tungsten, platinum, and manganese salts. The magnetically sensitive particles 14 can be ferromagnetic. Such magnetically sensitive particles 14 can include one or more suitable ferromagnetic material, such as iron, nickel, or cobalt. In some other applications, the magnetically sensitive particles 14 can be diamagnetic and be repelled from the applied magnetic field. Examples of diamagnetic materials include graphite, gold, bismuth, antimony, quartz, and silver. Based on the positions of the magnetically sensitive particles 14 in FIG. 1B or FIG. 1C, a measurement circuit can generate an indication of an applied magnetic field. This can measure the magnetic field based on positions of the magnetically sensitive particles 14 within the container 12.

### Particles in Medium Material

Particles can be embedded in medium material within a container, where mobility of the particles in the medium material changes with temperature. A property of the medium material can change in response to changes in temperature, and this property can affect mobility of the particles in the medium material. The property can be a phase of the medium material or a viscosity of the medium material. The medium material can be a phase change material that can change phase (e.g., solid, gel, liquid, vapor) in response to a change in temperature. In certain instances, the change in mobility of the particles can be associated with a phase change of the medium material that results from a change in temperature. In some instances, the change in mobility of the particles can be associated with a change in viscosity of the medium material that results from a change in temperature. The change in viscosity of the medium material can occur without a complete phase change of the medium material. The change in viscosity can occur in a medium material that is a gel or a liquid.

The change in state of the medium material affects mobility of particles within a container. The change in mobility of particles in the medium material can also affect sensitivity of another measurement by a system. For example, the medium material changing state can increase the mobility of particles such that the particles move more in response to the same stimulus (e.g., external magnetic field) to thereby increase sensitivity of magnetic field detection. The mobility of magnetically sensitive particles can depend on the viscosity of the medium material and the intensity of an external magnetic field.

The system can implement a sensor element that activates when a temperature crosses a threshold (e.g., goes above a threshold temperature or below a threshold temperature). Detecting movement of the particles can indicate that a minimum or maximum temperature has been reached. As the medium material goes through phases (e.g., melts, simmers, boils, etc.), the particles can become more agitated or move from their initial positions (before the temperature change affecting the phase change material). This can be detected and indicate that a specific temperature range has been reached. For example, if a container is positioned within a liquid or a solution, the system can be used to track temperature exposure. Monitoring the particles can provide an inference of the stage of the liquid or solution. Such monitoring can be performed continuously or intermittently.

In certain applications, a system can implement a sensor element that detects temperature based on particle movement associated with a change in viscosity of the medium material. This can be achieved by an electrical signal related to a position or cluster of particles or an optical detection of a position or cluster of particles or another method described elsewhere herein depending on the specifications a particular application. Such temperature detection can involve periodic or continuous evaluation of speed of particle movement. A stimulus to move the particles can be continuously applied (e.g., as an alternating current voltage or alternating applied magnetic field). Alternatively or additionally, the positions of the particles can be periodically reset and a stimulus can be applied to move the particles. A measurement circuit can access calibration information (e.g., as a look up table or formulaic relationship) between particle movement (e.g., speed) and temperature. The skilled artisan can readily obtain such calibration information for a given device configuration (medium composition, particle composition and shape, etc.) through routine experimentation.

An example of magnetically sensitive particles in a phase change material will be discussed with reference to FIGS. 21A and 21B.

### Non-Magnetically Sensitive Particles in Magnetically Sensitive Fluid

In some embodiments, a container can include non-magnetically sensitive particles in a magnetically sensitive fluid. The magnetically sensitive fluid can be a ferromagnetic fluid, a paramagnetic fluid, a diamagnetic fluid, or a magnetorheological fluid. The magnetically sensitive fluid can change density based on the characteristics of an external magnetic field and the particles can then change the depth where they are located within the fluid. The magnetically sensitive fluid can be a magnetorheological fluid that changes mechanical viscosity significantly when exposed to magnetic field. Such a fluid can reduce and/or prevent particle movement when magnetized and allow particle movement in the absence of a magnetic field.

Examples of magnetically sensitive fluids include ferrofluids made with particles of magnetic materials such as magnetite, maghemite or cobalt ferrite dispersed in a fluid, such as water or an organic solvent. The properties of the ferrofluid and density of the particles may be chosen for the specifications of a particular application.

The magnetically sensitive fluid can be liquid. A plurality of different types of non-magnetic particles can be included in the magnetically sensitive fluid. Positions of the different types of non-magnetic particles can be used to measure an applied magnetic field. With magnetic density separation, an indication of an applied magnetic field can be determined based on positions of the non-magnetically sensitive particles. While the particles need not be directly responsive to external magnetic fields, advantageously the particles can be chosen to facilitate sensing their positions when they are moved by the fluid’s response to external magnetic fields. Example materials include non-magnetic conductors (e.g., aluminium, charged particles such as particles with carboxylate or amino groups on the surface making them conductive but not magnetic, etc.), a plastic, foam, polyethylene terephthalate (PET), and silica particles. In certain applications, non-magnetic particles can be non-magnetic polystyrene particles. Non-magnetic polystyrene particles can be positively charged (e.g., by amine modification), unmodified, or negatively charged (e.g., by carboxyl modification). In some applications, non-magnetic particles can include streptavidin coated non-magnetic particles. Non-magnetic particles can be selected based on how they are to be detected in the system. For example, with optical detection, opaque non-magnetic particles can be used. The non-magnetic particles can be mechanically resilient. Any suitable principles and advantages of the embodiments described with reference to magnetically sensitive particles can be applied to non-magnetically sensitive particles within a magnetic fluid.

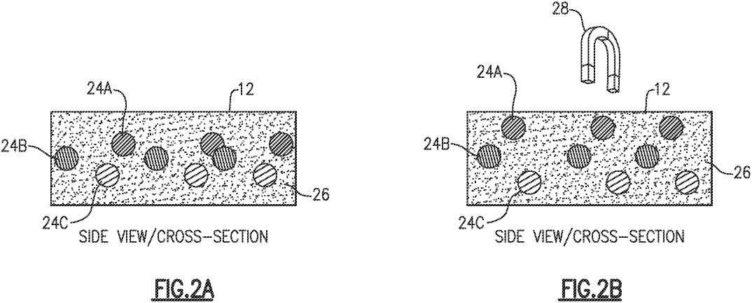

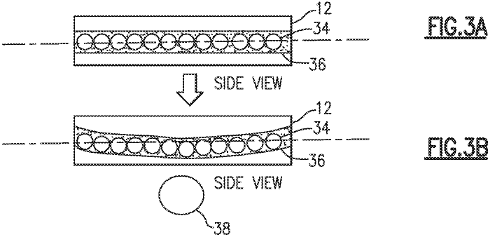

FIGS. 2A and 2B illustrate a container 12 that includes non-magnetically sensitive particles 24A, 24B, and 24C in a ferromagnetic fluid 26 according to an embodiment. The container 12 can be a sealed enclosure. The non-magnetically sensitive particles 24A, 24B, and 24C include a plurality of different types of particles different properties, such as shape, density, or weight. As illustrated, there are three different types of non-magnetically sensitive particles 24A, 24B, and 24C in the ferromagnetic fluid 26. The different types of non-magnetically sensitive particles 24A, 24B, and 24C can have the same or similar sizes and different densities. The non-magnetically sensitive particles 24A, 24B, and 24C can be electrically conductive in certain applications.

FIG. 2A shows an initial position of non-magnetically sensitive particles 24A, 24B, and 24C. A magnetic field source 28 can apply a magnetic field that causes the non-magnetically sensitive particles 24A, 24B, and 24C to move in the ferromagnetic fluid 26. A gradient in the magnetic field can cause density of the ferromagnetic fluid 26 to change, which can in turn cause the non-magnetically sensitive particles 24A, 24B, and/or 24C to move within the ferromagnetic fluid 26. The magnetic field applied by the magnetic field source 28 can cause the non-magnetically sensitive particles 24A, 24B, and 24C to move to the positions shown in FIG. 2B. A measurement circuit can detect the positions of at least some of the non-magnetically sensitive particles 24A, 24B, and/or 24C to generate an indication of the applied magnetic field. This can measure the magnetic field based on positions of at least some of the non-magnetically sensitive particles 24A, 24B, and 24C within the container 12.

In the embodiment of FIGS. 2A and 2B, the magnetic field does not directly attract non-magnetically sensitive particles. The magnetic field changes the density of the ferromagnetic fluid 26 depending on the field intensity and variation so the non-magnetically sensitive particles 24A, 24B, and 24C will move to a different level in the magnetically sensitive fluid 26.

Magnetically sensitive particles can also or alternatively be included in magnetically sensitive fluid in an embodiment. For example, diamagnetic particles can be included in a ferromagnetic fluid. Strong diamagnetic material, such as graphite, tends to generate a repelling force in a magnetic field.

### Layer of Material With Magnetically Sensitive Particles

In some embodiments, magnetically sensitive particles can be embedded in and/or deposited on a layer of material. The layer of material can be within a container. The container can be a sealed enclosure. The layer of material can be a film, a sheet of material, a flexible layer, or the like. For example, the layer of material can be a film with the magnetically sensitive materials embedded therein or a magnetic film or layer incorporated in a flexible laminate structure. As another example, the layer of material can be sheet of material, a polymer or composite or a prefabricated flexible layer with magnetic material deposited, embedded or adhered thereon. The magnetically sensitive particles can be implemented in accordance with any suitable principles and advantages disclosed herein.

The layer of material can be suspended within the container with or without surrounding fluid. In one example, the layer is suspended in air or an inert gas. In another example, the layer is suspended in a liquid with a viscosity selected to tune the film’s sensitivity (degree of movement in response) to external magnetic fields, similar to those described above for the magnetically sensitive particle embodiments. The layer of material can be tethered to the container. The layer of material can be tethered to the inside of the container and arranged such that the layer of material can deflect in response to a magnetic field. In certain applications, the layer of material can return to an initial position when no magnetic field is applied due, for example, to elasticity in the material of the layer.

The layer of material can be flexible substrate. Suitable materials for the layer include polymer materials such as SU-8, polyimide, polyvinyl alcohol, polyacrylic acid, polyvinyalcohol, polydimethylsiloxane, poly(3,4-ethylenedioxythiophene), Nafion, polyaniline, or the like. Some such polymer materials are conductive. In some instances, the layer can include a plastic such as polyethylene terephthalate (PET), polyethylene naphthalate (PEN), polyimide, or a transparent plastic. According to some applications, the layer can include a ferroelectric thin film. The layer can include thin glass. The layer can include a metal foil. The layer can have metal traces formed thereon and/or particles attached/embedded. The layer can alternatively or additionally include metallic non-magnetic material such as Au, Cu, or Al. The layer can include magnetic materials such as NiFe, Ni, NiFeCo, CoZrTa, CoFe, or the like. The layer can include gold in certain instances. In some instances, the layer can be a mesh rather than a continuous layer. The layer can be made with nano materials and constructed to flex, bend, or move in a desired way so that an external magnetic stimulus can interact with the incorporated magnetic particles. Any suitable principles and advantages of the embodiments described with reference to magnetically sensitive particles can be applied to layers of material with magnetically sensitive particles depending on the specifications a particular application.

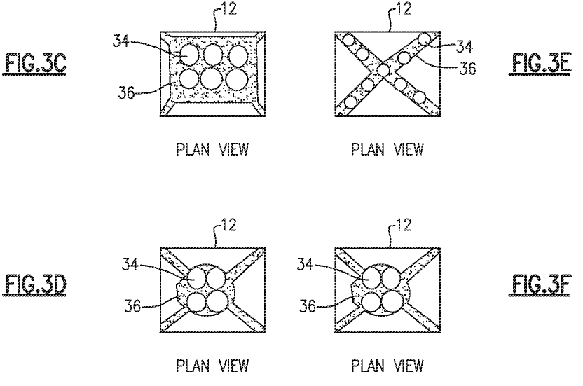

FIGS. 3A and 3B illustrate side views of a container 12 that includes a film 36 with magnetically sensitive particles 34 in two different states according to an embodiment. The film 36 includes the magnetically sensitive particles 34 embedded therein. The magnetically sensitive particles 34 can be diamagnetic, paramagnetic, ferromagnetic, or ferrimagnetic. For example, the magnetically sensitive particles 34 are diamagnetic in an embodiment. As another example, the magnetically sensitive particles 34 are paramagnetic as shown in FIG. 3B. As another example, the magnetically sensitive particles 34 can include a ferromagnetic material, such as iron, nickel, or cobalt. As one more example, the magnetically sensitive particles 34 can include ferromagnetic material, such as magnetite (Fe₃O₄). The film 36 can deflect and/or displace relative to a central axis in response to an applied magnetic field. Movement of the film 36 can produce a discernible electrical output, such as a capacitance. For example, as the film 36 moves, capacitors formed by the film 36 and the top and bottom of the container 12 can change. In this example, both capacitors are related in order to compensate for several effects (e.g., temperature). In some instances, the film 36 can include an electroactive polymer. In other examples, the particles can be non-magnetically sensitive and chosen for position detectability, and the film material can be magnetically sensitive. For example, such a magnetically sensitive material can include Ni, NiFe, CoFe, CoZrTa, Co, or the like. In certain applications, a magnetically sensitive layer without embedded non-magnetically sensitive particles can be implemented.

In FIG. 3A, no magnetic field is being applied and the film 36 is in an initial position. A magnetic field source 38 with magnetic properties applying a magnetic field causes the film 36 to move to the position shown in FIG. 3B. As shown in FIG. 3B, the film 36 can deflect toward the magnetic field source 38 in certain applications. A measurement circuit or sensing structures incorporated within the enclosure can detect the movement or proximity and/or position of the film 36 to generate an indication of the applied magnetic field. This can measure the magnetic field based on positions of the magnetically sensitive particles 34 within the container 12.

FIGS. 3C, 3D, 3E, and 3F illustrate examples of films 36 with embedded magnetically sensitive particles 34 within a container 12 in plan view according to embodiments. The film 36 can have any suitable shape for a particular application and can incorporate different material or structures (e.g., mesh, nanomaterials, composite layers, etc.) to facilitate desired movement depending on the specifications of a particular application. The magnetically sensitive particles 34 have any suitable pattern and/or arrangement within the film 36. One or more of the shape, size, location, pattern and construction of the particles can be optimized depending on the specifications of a particular application. In the illustrated examples, relatively elastic tethers facilitate deformation of the film 36 and attendant changes in position of the particles 34 in response to an external or applied magnetic field. One or more of the shape, size, and construction of the tethers to the container can be modified/optimized depending on the specifications of a particular application.

### Containers

In certain embodiments, the container is a sealed enclosure made from glass. This can enable the enclosure to be sealed similar to the technologies applied for assembling hermetically sealed semiconductor packaging. According to some embodiments, the container can be flexible, include a laminate, a composite, a ceramic, glass, or a metal. The container can include several different layers.

In certain applications, a hermetically sealed enclosure can be fabricated in a non-semiconductor/wafer fabrication environment. Some or all of such an enclosure can be exposed in a harsh environment. Examples of harsh environments include without limitation acidic environments, corrosive environments, and high temperature environments. Fabricating the enclosure and including particles for detecting a magnetic field within the enclosure can be carried out in a separate manufacturing location and/or process from the manufacturing location of an integrated circuit that is integrated with the enclosure. At a later stage of manufacturing, such as a packaging stage, the enclosure can be integrated with the integrated circuit and/or other components or processing circuitry. For example, the enclosure can be incorporated within a module or stacked with an integrated circuit that includes semiconductors and/or supporting circuitry and systems.

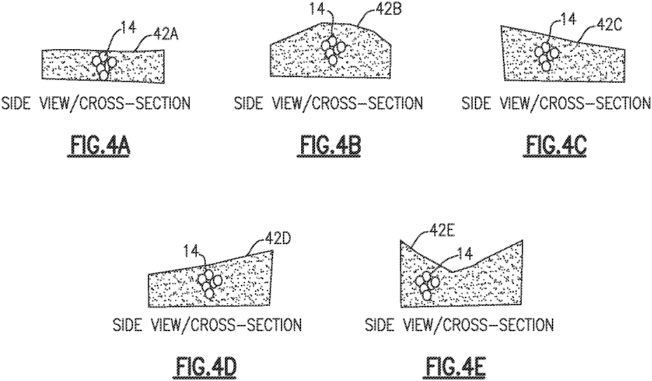

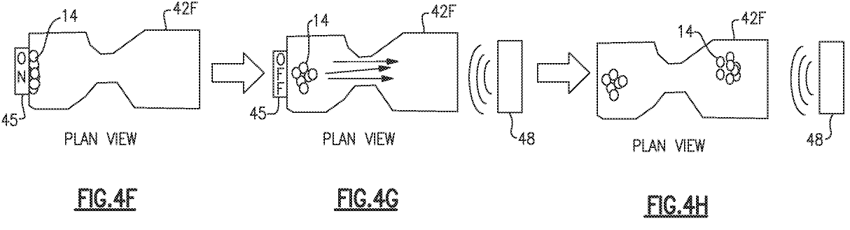

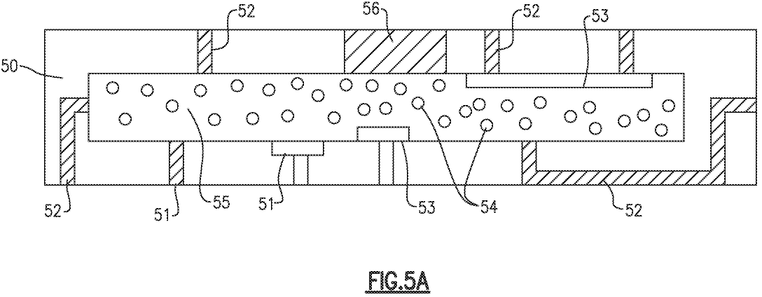

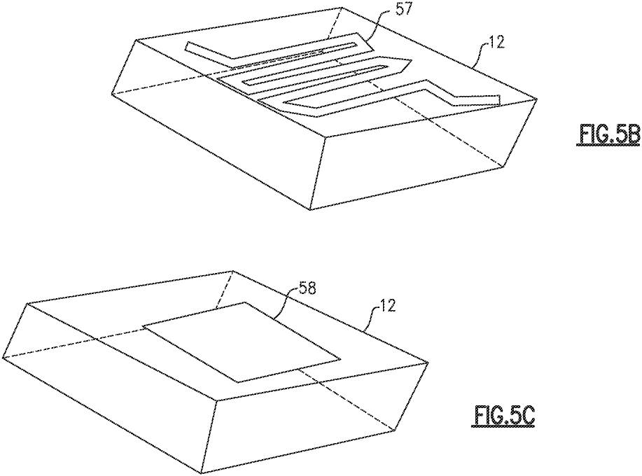

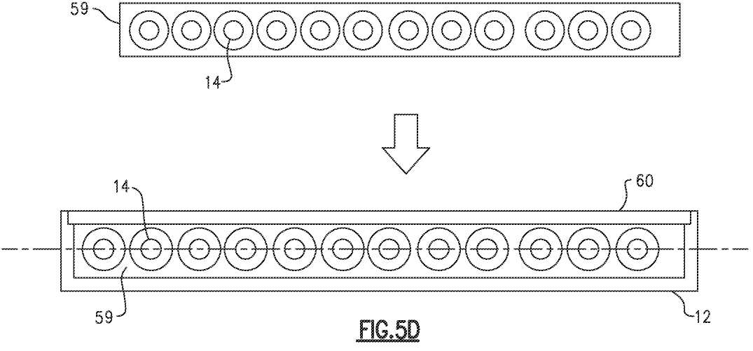

Containers for particles can have any suitable shape and size depending on the specifications of a particular application. Enclosures containing particles for magnetic field detection can be shaped to enhance and/or optimize sensing of magnetic fields and/or magnetic bodies. FIGS. 4A, 4B, 4C, 4D, and 4E illustrate example containers 42A, 42B, 42C, 42D, and 42E, respectively, with various cross-sectional shapes. Different fluid enclosure shapes can enable proximity and/or direction of magnetic bodies and/or fields to be adjusted for particular applications.

An enclosure can be shaped for desired particle movement paths/speeds/distance in the presence of an applied magnetic field. For example, FIGS. 4F, 4G, and 4H illustrate a plan view of a container 42F with a constricted region. Over time and/or with a minimal threshold field, particles can flow through the constricted region based on exposure to an applied magnetic field. For instance, in FIGS. 4G and 4H, magnetically sensitive particles 14 flow toward a magnetic field source 48 that has an associated magnetic field. A biasing structure 45 integrated with the container 42F can bring the magnetically sensitive particles 42 to an initial position. The magnetically sensitive particles 14 are in the initial position in FIG. 4F. The biasing structure 45 can be deactivated to allow the magnetically sensitive particles 14 to flow in response to an applied magnetic field. The biasing structure 45 can also be used as a reset mechanism to bring the magnetically sensitive particles 14 to the initial position. The container 42F and magnetically sensitive particles 14 can be used to detect a cumulative magnetic field exposure based on an amount of magnetically sensitive particles 14 that move through the constricted region. The relative sizes and shapes of the magnetic particles to the constricted region of the container can be modified and optimized depending on the specific requirements of the application.

In some instances, a semipermeable membrane can be included within the narrow side of the container 42F (or in a suitable location between the extreme ends of the container) so that the magnetically sensitive particles 14 find little resistance crossing towards one direction but not the opposite direction. That can allow magnetically sensitive particles 14 to move to one side and remain there even when the magnetic field is no longer present. If such a membrane is designed accordingly, the magnetically sensitive particles 14 can be impeded from moving back through the membrane, or moved through the membrane by applying a strong magnetic or electric fields to reset the device. The size of the particles, construction of semi-permeable membrane, use of a mesh material or any suitable combination of any or all these factors (or another suitable material) can be applied/modified/optimized based on the specifications of a particular application.

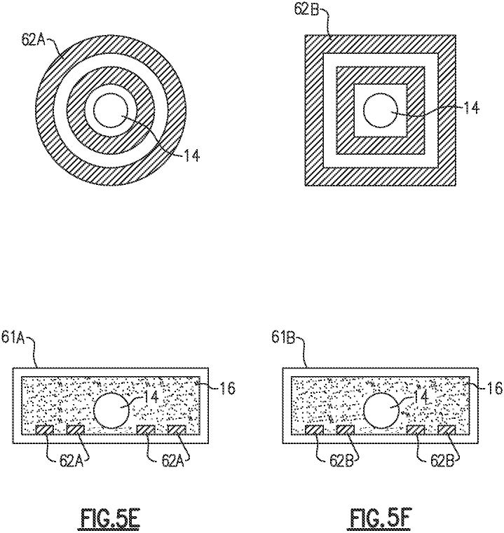

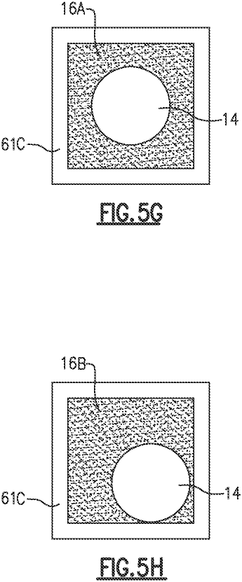

A container can include one or more integrated structures that can combine to enable specific functionality and sensitivity of the system being constructed depending on the specifications of a particular application. FIG. 5A illustrates an example enclosure 50 having a plurality of integrated structures according to an embodiment. One of more of these structures can be integrated with any of the containers or enclosures disclosed herein as suitable. As illustrated, the enclosure 50 includes conductive structures 51 and 52. The illustrated conductive structures 51 include vias and a conductive trace through or on packaging dielectric materials (e.g., printed circuit board (PCB) layers, encapsulating molding materials, ceramic, glass, composite, metallic, laminate, polymer, etc.). The enclosure 50 can include one or more structures 53 on a surface thereof (and/or also embedded within the layers of the enclosure 50). For example, a sensor, a conductive trace, or a coil can be included on an inner surface (as shown) or outer surface of the enclosure 50. The enclosure 50 can include electrically conductive paths 52 from an internal part of the enclosure 50 to external to the enclosure 50, which can also be provided in the form of traces, vias and/or lead frame materials. The enclosure 50 also includes particles 54 within a material 55. The particles 54 can be one or more of conductive, magnetically sensitive, paramagnetic,diamagnetic, ferromagnetic, or ferrimagnetic materials. The material 55 can be a fluid, a liquid, a gel, a paste, a foam, or a polymer that permits relative movement of the particles in response to magnetic fields. The material 55 can be electroactive. The enclosure 50 can include an optical window 56 such that a cluster or movement of particles can be optically detected. The optical window 56 can be incorporated into the container. Particle size/shape/colour can be such that a cluster of particles can be optically detected though the optical window. The particles 54 can be detected with a naked eye or with a suitable optical sensor integrated within the system.

FIG. 5B is a schematic isometric view of an example container 12 with an integrated heating element 57 according to an embodiment. The heating element 57 can be included on and/or within one or more layers of the container 12. The heating element 57 can be located in any suitable position of the container 12, such as on a top and/or a bottom of the container. The heating element 57 can be a resistive heating element, for example. Heat generated by the heating element 57 can affect a medium material, such as a fluid, within the container 12, where mobility of the particles in the medium material changes with temperature. The heat generated by the heating element 57 can cause particles in the medium material to move. In certain applications, the heating element 57 can heat the medium material to reset the positions of the particles. The heat itself can provide impetus to move particles to a reset (e.g., randomly distributed) position, or the stimulus (e.g., gravity, electrical or magnetic field) can be applied in a different orientation to reset the particle positions while the heating element 57 ensures mobility of the particles within the medium material. In some embodiments, heat can be applied before a measurement from the sensing system is recorded. This can ensure, for example, that the particles within the enclosure are starting from a known position or level within the enclosure. In certain embodiments, alternating magnetic fields can be applied to agitate the particles and generate heat through friction, allowing a phase change or a reduction in viscosity to permit resetting the device for temperature detection.

FIG. 5C is a schematic isometric view of an example container 12 with an integrated reset mechanism, in particular a piezoelectric element 58 according to an embodiment. The piezoelectric element 58 can include piezoelectric material included on and/or within one or more layers of the container 12. The piezoelectric element 58 can be located in any suitable position of the container 12, such as on a top and/or a bottom of the container. The piezoelectric element 58 can be activated to physically agitate particles in medium material or fluid within the container when the particles are mobile. This agitation can reset the positions of the particles. A combination of a reset mechanism and a heat source, such as the piezoelectric element 58 of FIG. 5C and the heating element 57 of FIG. 5B, can be employed in separate layers in and/or on the container 12 to ensure the medium material is in a state to allow ready particle movement during reset.

Agitation can also be employed to increase the sensitivity of detecting particle movement. The agitation from the piezoelectric element 58 can enhance detection of particle movement. In certain application, this can detect a phase change of the medium material. The agitation from the piezoelectric element 58 can enhance detection of particle movement to detect a change in viscosity of the medium material. With the piezoelectric element 54, there can be intermittent agitation and detection of particle movement. Intermittent detection of particle movement over time can be used to detect whether a threshold temperature has been exceeded (e.g., in cold storage applications) and/or whether a target temperature level has been attained (e.g., in sterilization applications). In certain applications, the piezoelectric structures can be enabled at specific intervals when, for example, the particle location is detected and logged. One or more of the size, shape, construction, and location of the piezoelectric structures can be optimized and modified depending on the specifications of a particular application.

The medium material can include a film or gel that becomes softer and/or more malleable above a certain temperature such that particles 14 move. A piezoelectric element or other agitation element can pulse the film and/or the particles to detect whether a temperature has been reached.

FIG. 5D illustrates particles in a film 59, along with an enclosure with a flexible surface 60 around the film 59 and the particles 14. The container 12 of FIG. 5D can be used with any suitable principles and advantages disclosed herein, such as piezoelectric pulsing. Although a flexible top surface 60 is illustrated in FIG. 5D, any suitable surface of the containers disclosed herein can be flexible and/or a container can include two or more flexible surfaces in certain applications.

In certain applications, a container can include an integrated patterned structure that is conductive and/or magnetically sensitive. The patterned structure can be used for sensing in some instances. For example, the pattern can enable particle movement in specific directions or clusters in specific locations to be detected. The patterned structure can be used for biasing in some instances. FIGS. 5E and 5F illustrate example enclosures with patterned structures. The patterned structures are shown in side view and in plan view in these figures. FIG. 5E illustrates an enclosure 61A with a patterned structure 62A. FIG. 5F illustrates an enclosure 61B with a patterned structure 26B. Patterned structures 62A and 26B are two examples of conductive and/or magnetically sensitive patterned structures. The patterned structures can be modified to have a suitable shape depending on the specifications of a particular application. One or more of the particle shape, size and construction can also be modified as desired.

FIGS. 5G and 5H are schematic plan views of an example enclosure 61C with a magnetically sensitive particle 14 in phase change medium material 16 according to an embodiment. In FIG. 5G, the phase change medium material 16A can initially be provided in a first state (e.g., a solid state) where a magnetically sensitive particle in the phase change material is in a fixed position. Above a threshold temperature, the phase medium change material 16 can change to a second state (e.g., a liquid state) as shown by the phase change medium material 16B in FIG. 5H where the magnetically sensitive particle 14 is mobile. The enclosure 61C can include one or more suitable integrated structures, such as one or more magnetic sensing structures, one or more conductive traces, one or more conductive or optical vias, incorporate a specific shape to limit the extents of particle movement, etc. Traces can be provided within the enclosure 91C to detect contact or changes in position of the particle 14 that can occur with the phase change, allowing electrical detection of the phase change as an indication of crossing the threshold temperature.

### Magnetically Sensitive Particles

Magnetically sensitive particles can have one or more properties such that the magnetically sensitive particles move in a desired way to the magnetic stimulus. For example, magnetically sensitive particles can be constructed, shaped, patterned, or the like so the magnetically sensitive particles respond to a magnetic stimulus in a desired way. As one example, a spiral shaped magnetic particle can respond to a magnetically induced force and move through fluid differently than a spherical or square shaped particle. The viscosity of the fluid and the shape of the magnetically sensitive particle can be balanced for movement of the magnetic particle in response to an applied magnetic field. The magnetically sensitive particles can be coated with an electrically conductive material (e.g., gold) such that when a certain amount of particles cluster or align, a conductive path is formed between electrical contacts in a container. The magnetically sensitive particles can be coated with a coating to enhance optical detection, such as a coating to achieve one or more of a desired optical contrast, color, fluorescence, luminescence, or another optical property. In certain instances, magnetically sensitive particles can be coated so as to not chemically react with a surface or other structure.

In some instances, one or more internal sections of an enclosure can be patterned with magnetic material to detect clusters of particles in specific regions. The shape of magnetically sensitive particles can affect how the magnetically sensitive particles move and cluster in such applications. Depending on the outermost material, magnetically sensitive particles may stick together. In some applications, the magnetically sensitive particles can be coated with a thin material, such as Teflon or another polymer, so that there is little or no potential for the magnetically sensitive particles to stick together and/or cluster for any reason other than a response to a magnetic field. The enclosure can incorporate one or more conductive vias and connections from the internal surfaces to the external. The enclosure can incorporate one or more optical conduits and/or areas that facilitate optical detection of particle clusters or movement.

Magnetically sensitive particles can be constructed to move and/or respond in different ways. Sensitivity, such as movement, to certain field strengths can be improved with certain particle constructions, shapes, etc. The magnetically sensitive particles can be combined with and/or embedded within non-magnetic material to provide the effect of a partially patterned structure. The combined structure can then be inserted within a fluid, a gel, or a film.

In some instances, magnetically sensitive particles can include an outer coating that is magnetically sensitive. As an example, magnetically sensitive particles can be a polystyrene bead coated with nickel or another magnetically sensitive material. Such magnetically sensitive particles can have an overall density of magnetic material that is lower than a homogenous sphere of magnetically sensitive material. In some other examples, magnetically sensitive particles can have magnetically sensitive core materials and coatings selected to enhance or inhibit interaction with each other and/or the surrounding fluid. For example, the outer coating could be polystyrene, PTFE, Teflon, or some other polymer that can inhibit particles sticking together other than in a desired way as a response to stimulus from a magnetic field.

In certain instances, magnetically sensitive particles have an electrically conductive outer surface. For example, magnetically sensitive particles can be coated with gold. With such magnetically sensitive particles, an electric contact between two electrodes in the container can be closed.

Magnetically sensitive particles can have a coating with one or more specific optical properties in some applications. With such a coating, one or more of a contrast, a color, luminescence or fluorescence can be achieved. The coating with one or more specific optical properties can aid optical detection of magnetically sensitive particles.

Magnetically sensitive particles can be ferromagnetic, ferrimagnetic, paramagnetic, or diamagnetic. Diamagnetic particles are repelled by a magnetic field. In contrast, paramagnetic and ferromagnetic particles are attracted by a magnetic field.

The magnetically sensitive particles can have any suitable size for a particular application. In certain applications, magnetically sensitive particles are micrometer scale or larger. In some applications, magnetically sensitive particles are millimeter-scale particles. Magnetically sensitive particles can be larger than millimeter-scale. In certain applications, magnetically sensitive particles can have a particle width in a range from about 50 nanometers to 1 millimeter. In some such applications, particle width can be in a range from about 0.1 micron to 100 microns. In some of these applications, particle width can be in a range from about 0.5 micron to 100 microns.

Magnetically sensitive particles can have a shape to influence their movement and/or orientation in the fluid such that their sensitivity to the magnetic field stimulus is enhanced and/or optimized. In certain applications, it may be desirable to have a non-symmetrical magnetically sensitive particle so that the magnetically sensitive particle moves in a particular way when exposed to a magnetic field. A combination of the shape of the magnetically sensitive particle and how the magnetically sensitive particle is embedded or suspended in a fluid/gel can be receptive to magnetic stimuli in particular directions and/or intensities. A particular particle shape combined with a fluid or gel of a particular viscosity can provide a desired sensitivity to a magnetic stimulus. Different particle sizes and shapes can be combined as desired for a range of target sensitivities within a system. The particles can also be constructed to have a shape that, for example, facilitates clustering or physical joining together of groups of particles.

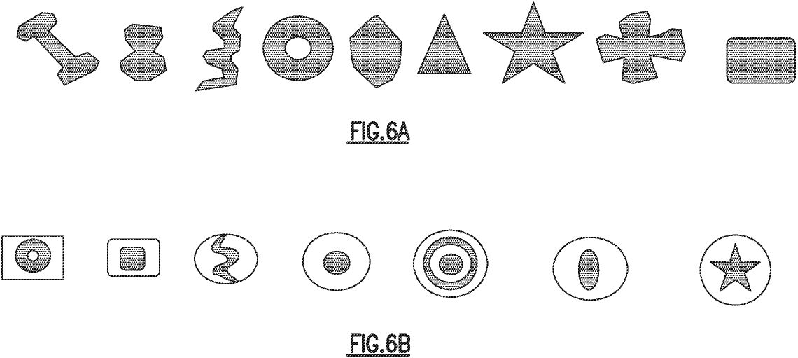

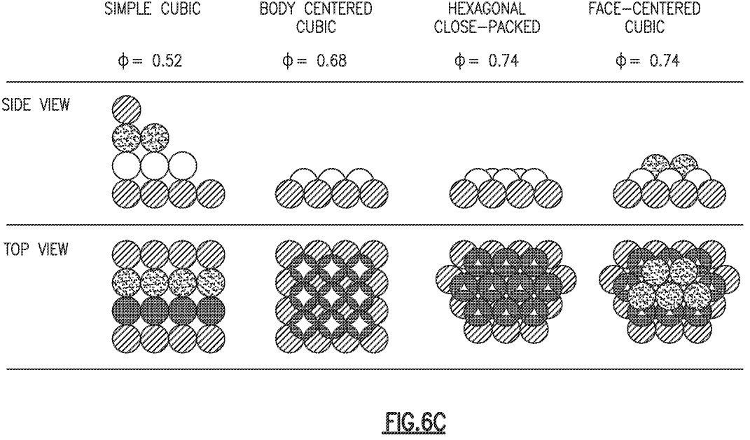

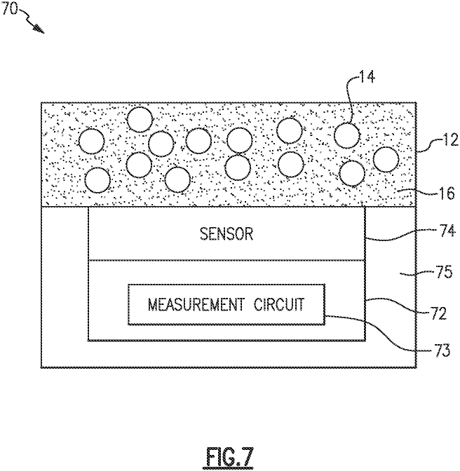

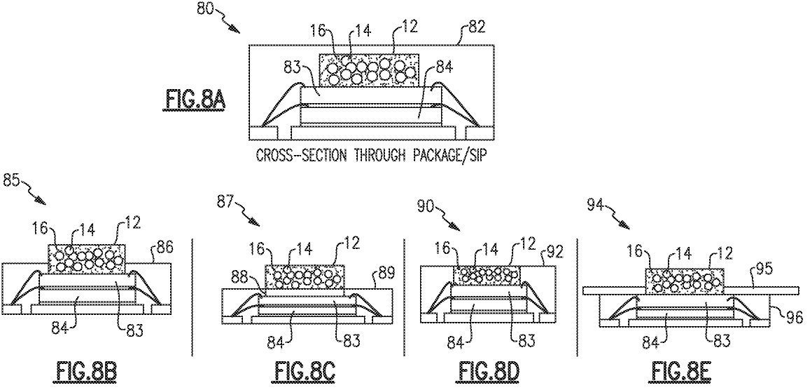

FIG. 6A illustrates example shapes of magnetically sensitive particles. The magnetically sensitive particles can be added to an inert, non-magnetic material to form a combined structure. FIG. 6B illustrates example combined structures with magnetically sensitive particles included within non-magnetic material. Various processes, such as molding, printing, plating, sputtering, laser cutting, laminating, and the like, can be used to fabricate composite particles incorporating magnetically sensitive particles so that the magnetically sensitive particles react in a desired manner to a magnetic field. For example, with an outer non-magnetic layer, when a number of the composite particles come together, they may be held in a cluster by a magnetic field/force. Such composite particles can have non-magnetic material come into physical contact with one or more other composite particles. Such a construction can be desirable to allow release of such composite particles from one another in the absence of the magnetic field. For example, spherical particles with magnetic cores and covered with polystyrene/PTFE may be less likely to stick together and may bounce off each other. A combination of particle shape (e.g., spiral shape, propeller shape, etc.) and fluid viscosity can determine sensitivity and/or speed of a response to a magnetic field stimulus. One or more of the particle shape, construction and size can be modified and optimized depending on the specifications of a particular application.

Magnetically sensitive particles can have various sizes and densities. If all particles are the same size, a contact surface area can be relatively small. By using a plurality of sizes (e.g., large and small), a bridging structure can have more contact points. This can allow smaller particles to reduce resistance / increase current carrying capability. FIG. 6C shows examples of how combining different types of particles can result in clustering with different shapes, which can be useful for detection purposes.

### Container With Integrated Circuit

Magnetic field measurement systems can include a container (or enclosure), one or more particles within the container, and a measurement circuit configured to output an indication of an applied magnetic field based on position(s) of at least one particle within the container. The container can be integrated with, for example co-packaged with, an integrated circuit and/or other components. The container can include an electrical connection to the integrated circuit. The integrated circuit can include some or all of the measurement circuit. In some instances, the integrated circuit can also include a sensor that senses position(s) of particles within the container. The sensor can output a signal to the measurement circuit. In some other applications, the measurement circuit can generate a measurement of the applied magnetic field without a separate sensor.

FIGS. 7 to 12 illustrate systems and modules that include a container integrated with an integrated circuit that includes a measurement circuit. Any suitable principles and advantages of these embodiments can be implemented together with each other. Moreover, the embodiments of FIGS. 7 to 12 can be implemented with any other suitable principles and advantages disclosed herein related to containers, particles, and magnetic field measurements disclosed here can be implemented together with any of the embodiments of FIGS. 7 to 12.

FIG. 7 is a schematic block diagram of a magnetic field sensing system 70 according to an embodiment. In the magnetic field sensing system 70, a magnetic field measurement is generated based on positions of particles within a container. The magnetic field sensing system 70 includes a container or enclosure 12 enclosing fluid 16 and magnetically sensitive particles 14 suspended within the fluid 16. An integrated circuit 72 is integrated with the container 12. As illustrated, the integrated circuit 72 is vertically integrated with the container 12. The integrated circuit 72 includes a measurement circuit 73. A sensor 74 is also integrated with the container 12. A packaging structure 75 can protect the integrated circuit 72 and the sensor 74. The container 12, the sensor 74, and the integrated circuit 72 can be co-packaged.

The sensor 74 can sense position of the magnetically sensitive particles 14. The sensor 74 can be a magnetic sensor, a capacitive sensor, a MEMS based sensor, an optical sensor, a resistive sensor, an inductive sensor or any other suitable sensor that can detect movement and/or positions of the magnetically sensitive particles. The sensor 74 can be configured to detect any change of magnetic field strength or distribution caused by movement of the magnetically sensitive particles. For example, the sensor 74 can be configured to detect a change from equally distributed magnetically sensitive particles to multiple clusters. The sensor 74 can be configured to detect a change from equally distributed magnetically sensitive particles to a single cluster having an arbitrary position. In some instances, the sensor 74 can detect a dynamic change of particle position.

The sensor 74 can be separately formed from the integrated circuit 72 and integrated with the integrated circuit 72 by way of packaging. The sensor 74 can be larger than the integrated circuit 72. The sensor 74 and the integrated circuit 72 can be formed by different fabrication processes. As illustrated, the sensor 74 for detecting position of magnetically sensitive particles is positioned external to the container 12 and separate from the integrated circuit 72 that includes the measurement circuit 73.

In some other embodiments, a sensor can be included within a container. According to various embodiments, a sensor can include elements on an integrated circuit that includes the measurement circuit and also elements external to the integrated circuit. In some embodiments, an integrated circuit can include both a sensor and circuitry of a measurement circuit.

The illustrated integrated circuit 72 includes the measurement circuit 73. In some other applications, circuitry of a measurement circuit can be included both on an integrated circuit and external to an integrated circuit (e.g., as one or more standalone circuit elements, on one or more other integrated circuits, etc.). The measurement circuit 73 generates an indication of an applied magnetic field based on position of the magnetically sensitive particles 14 within the container 12. The measurement circuit 73 can include any suitable circuitry to generate such an output. The measurement circuit 73 can include semiconductor devices, such as silicon devices and other components (chiplets, passives, discrete circuit elements, etc.) as desired depending on the specifications of a particular application. The measurement circuit 73 can process an output of the sensor 74 to generate the indication of the applied magnetic field. The measurement circuit 73 outputs a measurement of the applied magnetic field. The measurement circuit 73 can perform any of the comparative measurements disclosed herein. For example, the measurement circuit 73 can generate a measurement based on comparing a first measurement associated with the position of one or more first particles in a first compartment and a second measurement associated with position of the one or more second particles in a second compartment. As another example, the measurement circuit 73 can generate a measurement based on comparing a first measurement and a second measurement, where the first measurement is associated with positions of the at least two types of particles, and where the second measurement is associated with positions of at least some particles of the two types of particles moving in response to an external stimulus relative to the positions associated with the first measurement. The sensitivity of the system can be modified by modifying component parts in a manner described herein (e.g., particle size or shape or construction, fluid or gel type, enclosure shape, functionality incorporated within enclosure (e.g., optical window, sensing structures, piezoelectric structure, heating element etc.), etc.).

The indication of the applied magnetic field can be indicative of one or more of time of exposure to and intensity of a magnetic field, a direction of a magnetic field, an angle of a magnetic field, an intensity of a magnetic field, a rotation of a magnetic field, a profile of magnetically sensitive particles, a time domain change in a magnetic field (e.g., frequency and/or harmonics), or the like.

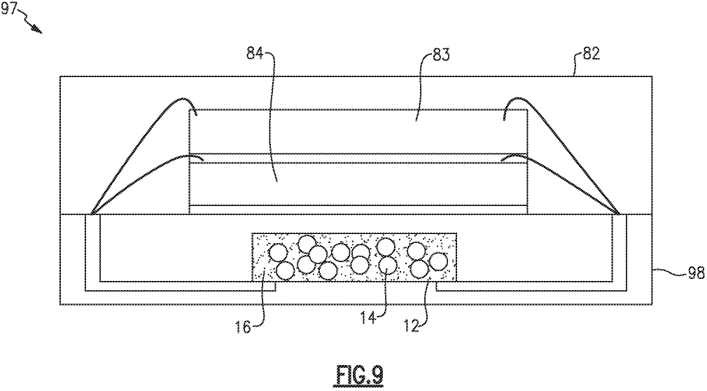

A container including particles can be included in a system in package (SIP). A SIP is an example of a packaged module. The container can be positioned close to a surface of a packaging structure or exposed through an opening in a packaging structure for sensing a magnetic field. In certain applications, an opening in the packaging structure can leave at least a portion of the container exposed to an external environment. The packaging structure can include a molding material, a sealed cavity or “can,” a laminate material, a composite material, or any other suitable structure to protect integrated circuits. An applied magnetic field causes particles to move within the container. A concentration of particles can produce a discernible electrical change within the system that indicates a presence/concentration of a magnetic body and/or a magnetic field. A measurement circuit of an integrated circuit of the SIP can output an indication of the magnetic field based on positions of the particles in the container. The SIPs can function in harsh environments, such as hot environments, acidic environments, humid environments, or corrosive environments. FIGS. 8A to 9 illustrate example cross-sectional schematic view of SIPs according to embodiments.

FIG. 8A illustrates an SIP 80 with a container or enclosure 12 with fluid 16 and magnetically sensitive particles 14 in the fluid 16. In the SIP 80, the container 12 is close to a surface of a packaging structure 82. The container 12 is stacked with a sensor 83 (or substrate or die incorporating a sensing element) and an integrated circuit 84. The integrated circuit 84 includes circuitry of a measurement circuit that outputs an indication of the applied magnetic field. In certain applications, the sensor 83 is included on an integrated circuit. According to some other applications, the sensor 83 is not included on an integrated circuit. The integrated circuit 84 can be application specific integrated circuit (ASIC). The integrated circuit 84 can include a semiconductor die. The sensor 83 can be on a semiconductor die. Elements of the system can be placed side by side instead of stacked vertically. The elements within the system can be connected using suitable technologies including, but not limited to, conductive traces, wire bonds, solder bumps, plated tracks, vias etc. Chiplets, passives, discrete circuit elements and/or other components, although not shown in FIG. 8A, can be included in the SIP 80 depending on the specifications of a particular application.

FIG. 8B illustrates an SIP 85 with a container 12 that is exposed through an opening in a packaging structure 86. The packaging structure 86 can be a molding compound, however, different packaging constructions could be used (e.g., pre-molded cavity, ceramic/hermetic, metal can, etc.) depending on the specifications of ta particular application. The container 12 is exposed through a top of the SIP 85. The container or enclosure 12 of the SIP 85 can be exposed to a harsh environment. The construction of the container or enclosure 12 can be modified depending on the specification of a particular application. For example, the container 12 can be a laminate or flexible composite or glass or metal or silicon or ceramic or another suitable material.

FIG. 8C illustrates an SIP 87 with a container 12 that is connected to an integrated circuit 83 though one or more intermediate layers 88. The one or more intermediate layers 88 can include one or more electrical connections between the container 12 and the integrated circuit 83, such as wiring layers in a circuit board (e.g., PCB or ceramic packaging substrate), interposer, plated or sputtered connections, or anisotropic conductive paste or film, or redistribution layers (RDLs). In the SIP 87, the container 12 can be exposed to a harsh environment. A packaging structure 89 covers less of the container 12 than the packaging structure 86 of the SIP 85.

FIG. 8D illustrates an SIP 90 with a container 12 that is flush with a surface of a packaging structure 92. The container 12 of the SIP 90 is exposed through an opening in the packaging structure 92.

FIG. 8E illustrates a SIP 94 with a protective layer 95 over a packaging structure 96. The protective layer 95 is an intermediate or protective layer that can protect the sensor 83 and integrated circuit 84 from a harsh environment. The protective layer 95 can include a heat shield, stainless steel, a cooling plate, an anti-corrosive material, a hermetic shield, or the like. The protective layer 95 can protect components on the SIP 94 from a harsh environment. A container 12 can be exposed through an opening in the package structure 96 and the protective layer 95.

FIG. 9 illustrates a SIP 97 that includes a container 12 embedded in a laminate 98. The laminate 98 can be a printed circuit board. Embedding the container 12 in the laminate 98 can be useful in applications where a source of magnetic field is placed on an opposite side of the laminate 98 relative to the sensor and the integrated circuit 84. The laminate material can also be constructed to incorporate other components and features (e.g., passives, discrete circuit elements, optical windows, sensing structures, heating elements, piezoelectric structures, etc.) depending on the specifications of a particular application. In such applications, the magnetic field source could be closer to the container 12. In the SIP 97, the container 12 can be electrically connected to sensor 83 and/or integrated circuit 84 by way of electrical connections in the laminate 98 and conductive features, such as through mold vias, traces, solder bumps, wire bonds, lead frames, anisotropic paste or film, flex with conductive traces, paste, etc., enclosed by the packaging structure 82.

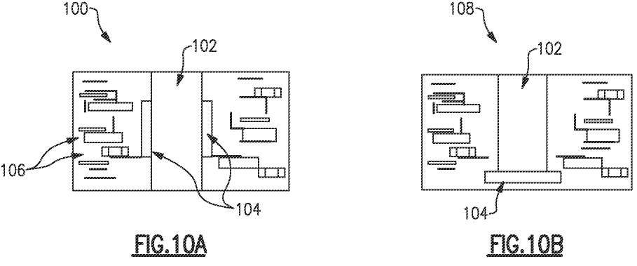

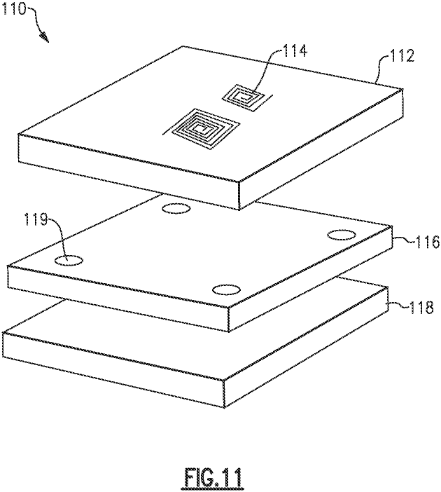

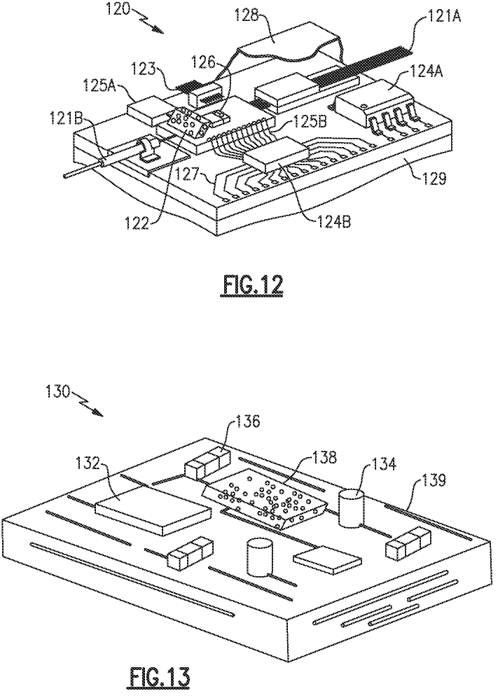

An integrated system can include an opening with an embedded structure. One or more enclosures with particles that move in response to an applied magnetic field can be exposed by the opening. The opening can be incorporated to detect magnetic stimuli in specific areas within an embedded system. An integrated circuit with a measurement circuit (as well as one or more of discrete circuit elements, passives, and/or other components) can be integrated with the enclosure in the embedded structure. The integrated circuit can be a processing die that includes circuitry of a measurement circuit. FIGS. 10A and 10B illustrate examples of integrated systems with enclosures containing magnetically sensitive particles according to embodiments.

FIG. 10A illustrates an integrated system 100 with an opening 102 within an embedded structure. The integrated system 100 includes containers illustrated as enclosures 104 with magnetically sensitive particles in fluid or gel. Integrated circuits 106 of the integrated system 100 include circuitry of measurement circuits for generating an indication of the applied magnetic field. The enclosures 104 are integrated with the integrated circuits 106, such by way of embedding in a laminate or build up structure or can incorporate a pre-molded structure with elements of common overmold, mounting on a common packaging substrate and/or surrounding with a common enclosure (e.g., “can” with an opening or window). The enclosures 104 are positioned on opposing sides of the opening 102 in FIG. 10A. The methods used to construct the system and dimensions and/or shape of opening 102 can be modified and/or optimized using appropriate packaging technologies depending on the specifications of the system.

FIG. 10B illustrates an integrated system 108 with an opening 102 within an embedded structure. The integrated system 108 includes a container in the form of an enclosure 104 with magnetically sensitive particles in fluid or gel. Integrated circuits 106 of the integrated system 108 includes circuitry of a measurement circuit for generating an indication of the applied magnetic field. The enclosure 104 is integrated with the integrated circuit 106, such as by way of embedding in a common overmold, mounting on a common packaging substrate and/or surrounding with a common enclosure (e.g., “can” with an opening or window). The enclosure 104 is positioned at an end of the opening 102 in FIG. 10B. The methods used to construct the system and dimensions and/or shape of opening 102 can be modified and/or optimized using appropriate packaging technologies depending on the specifications of the system.

Magnetic field measurement systems can wirelessly communicate with another device. Such a system can include one or more antennas (incorporated within the system) that can wirelessly transmit the indication of the applied magnetic field generated by the measurement circuit. The one or more antennas can wirelessly communicate any other suitable information. A system can be arranged such that a certain detected (or inferred magnetic related parameter), for example confirming proximity, presence, magnetic field intensity and/or direction, particle movement etc., can initiate a flag or alarm and/or result in initiating an action within the system.

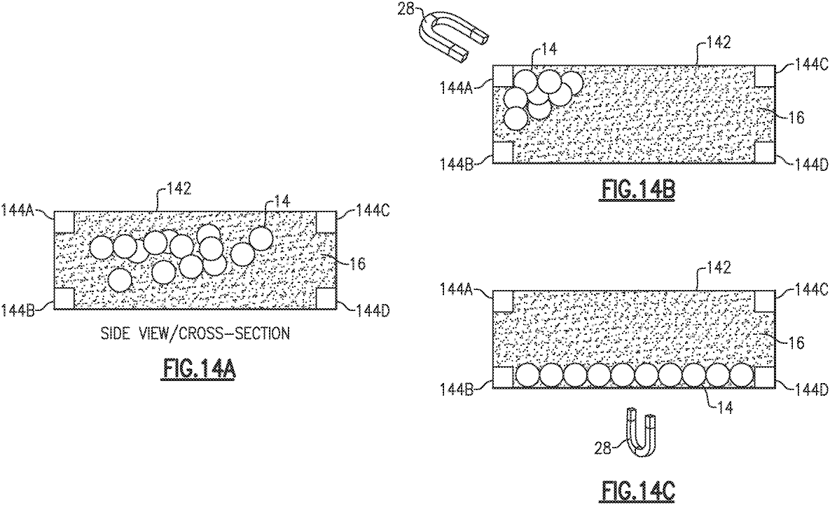

FIG. 11 illustrates an exploded schematic view of an example magnetic field measurement system 110 according to an embodiment. The magnetic field measurement system 110 includes a wireless communication layer 112 that includes one or more antennas 114, a layer 116 including an integrated circuit that includes circuitry of a measurement circuit, and a layer 118 that includes an enclosure with particles that move in response to an applied magnetic field in accordance with principles and advantages disclosed herein. Conductive vias 119 and/or traces can electrically connect layers of the magnetic field measurement system 110. The vias, traces and conductive paths can be sputtered, plated, use wire bonds, anisotropic conductive film or paste or any other suitable means of constructing electrically conductive paths. The one or more antennas 114 can include a coil, for example. The one or more antennas 114 can be included in a radio frequency identification (RFID) tag. The wireless communication layer 112 can include circuitry to support wireless signal transmission, or such circuitry may be provided in a lower layer, such as the layer 116. The circuitry to support wireless signal transmission can encrypt data for wireless signal transmission. The one or more antennas 114 can transmit encrypted data. A wireless communication layer can be incorporated within a SIP, module, or system in a number of ways. It can be stacked or placed side by side or heterogeneously constructed using chiplets (with incorporated coils and structures). The sensing system can also incorporate conductively coupled and/or optical methods of communication, with examples disclosed herein. The system construction can be modified and optimized depending on the specifications of a particular application.

Containers with particles that move in response to an applied magnetic field can be included in various modules. FIG. 12 illustrates photonic module 120 that includes a container in the form of an enclosure 122 with particles that move in response to an applied magnetic field according to an embodiment. As the particles change position depending on external magnetic fields, photodetectors and/or optical fibers can detect this change and transfer data to an integrated circuit 124. A light source 126, such as a laser, can be used in optical detection of particles within the enclosure 122. The integrated circuit 124 includes circuitry of a measurement circuit. The photonic module 120 can include one or more of optical fibers 121A, lensed optical fibers 121B, micro-optics 123, phonic wire bonds 125A, wire bonds 125B, a flip chip integrated circuit 124B, high speed electrical interposers 127, a packaging structure 128, and a thermal management system that can include microfluidics 129.

FIG. 13 illustrates an electronic module 130 with electronic elements 132, 134, and 136 and an enclosure 138 with particles that move in response to an applied magnetic field according to an embodiment. The electronic elements 132, 134, and 136 and the enclosure 138 are integrated by mounting and electrical connection to a common circuit board 139. The electronic elements include an integrated circuit 132 with circuitry of a measurement circuit. The electronic elements can also include a sensor that provides an output to the measurement circuit. A module, system, or SIP can also include circuitry that encrypts the output of the sensor.

### Measurements

Position and/or movement of particles can be measured in a variety of different ways. Without limitation, example measurements include case conductance measurements, zero-power direction detection measurements, cumulative magnetic field exposure detection measurements, microelectromechanical systems based measurement, optical measurements, and capacitive measurements. Example measurement systems and methods are discussed with reference to FIGS. 14A to 25. These measurement systems can include particles and containers in accordance with any suitable principles and advantages disclosed herein. Any suitable principles and advantages of the measurement systems disclosed herein can be implemented together with each other.

Positions of particles can be determined based on a conductive case measurement. A container enclosing fluid can be partially or completely conductive. A plurality of contacts can be provided on the container for taking a measurement associated with particle location.

FIGS. 14A, 14B, and 14C illustrate an example system where positions of particles can be measured by a case conductance measurement according to an embodiment. A container 142 enclosing a fluid 16 and magnetically sensitive particles 14 can be metallic or incorporate a metallic and/or electrically conductive area constructed to facilitate a conductance measurement. A plurality of metal contacts 144A, 144B, 144C, and 144D are included on the container 142. As illustrated, the metal contacts 144A, 144B, 144C, and 144D are positioned on corners of the container 142. A case conductance can be measured using a measurement circuit connected to the metal contacts 144A, 144B, 144C, and 144D. For example, impedance can be measured by applying a voltage to one or more of the metal contacts 144A, 144B, 144C, and 144D and measuring current. This measurement is indicative of positions of the magnetically sensitive particles 14 within the container 142. Case conductance can also be measured for non-magnetically sensitive particles in magnetically sensitive fluid.

A baseline case conductivity of the container 142 can be known. The system can be calibrated. For example, the magnetically sensitive particles 14 can be positioned as shown in FIG. 14A when no magnetic field is being applied, and the conductivity between each combination of two contacts 144A, 144B, 144C, 144D can be measured. Note that these baseline conductivities can be influenced by the materials of the container 142 (e.g., glass) and fluid 16. The magnetically sensitive particles 14 can align relative to a magnetic field and/or lines of flux.

A magnetic field source 28 can apply a magnetic field to cause the magnetically sensitive particles 14 to move to the positions shown in FIG. 14B. A change in resistivity can indicate positions of the magnetically sensitive particles. By measuring current using metal contacts 144A, 144B, 144C, 144D, positions of the magnetically sensitive particles 14 can be determined based on the change in resistivity or conductivity due to movement of the magnetically sensitive particles 14 from the positions shown in FIG. 14A to the positions shown in FIG. 14B. This change in resistivity or conductivity is indicative of the magnetic field applied by the magnetic field source 28. In particular, strength, intensity, a direction, and/or location of the applied magnetic field can be determined by comparing the measurements under influence of the magnetic field source 28 against the baseline measurements.

The magnetic field source 28 can apply a magnetic field to cause the magnetically sensitive particles 14 to move to the positions shown in FIG. 14C. By measuring current using metal contacts 144A, 144B, 144C, 144D, positions of the magnetically sensitive particles 14 can be determined based on the change in resistivity due to movement of the magnetically sensitive particles 14 from the positions shown in FIG. 14A to the positions shown in FIG. 14C. This change in resistivity is indicative of the magnetic field applied by the magnetic field source 28. A strength, direction and/or location of the applied magnetic field can be determined.

Magnetically sensitive particles with different properties can be used in case conductance measurements to determine an intensity of an applied magnetic field. For example, magnetically sensitive particles with different densities, different sizes, and/or different weights can be used to determine intensity of an applied magnetic field.

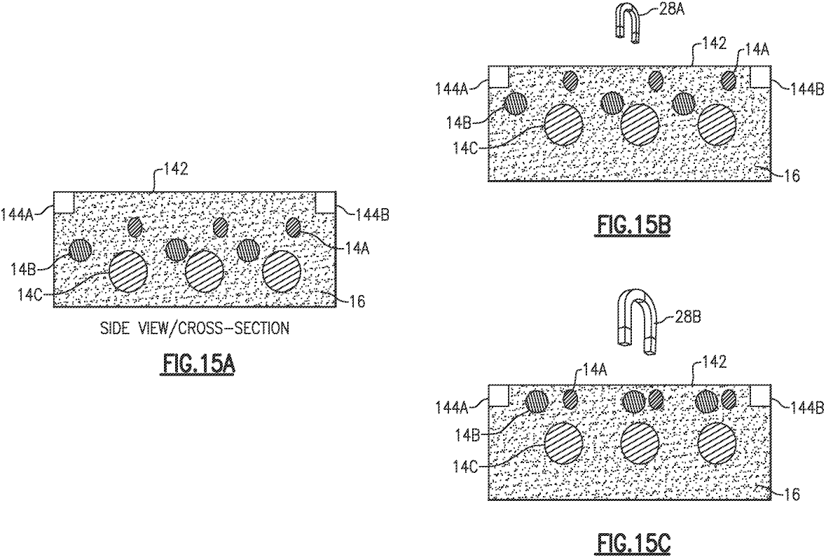

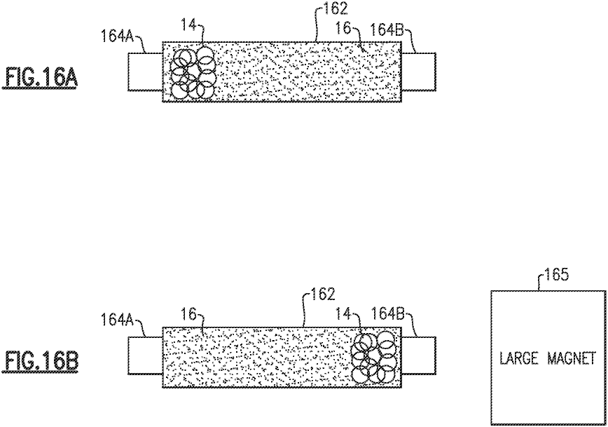

FIGS. 15A, 15B, and 15C illustrate a system for detecting magnetic field intensity with case conductance measurement according to an embodiment. Magnetically sensitive particles 14A, 14B, and 14C can be distributed in fluid 16 within container 142 depending on size of the magnetically sensitive particles 14A, 14B, and 14C.

A magnetic field source 28A can apply a magnetic field having a first intensity. This can cause magnetically sensitive particles 14A to come in contact with a surface of the container 142 as shown in FIG. 15B. The magnetic field applied by the magnetic field source 28A is not sufficiently strong to bring the magnetically sensitive particles 14B and 14C in contact with the container 142. The applied magnetic field can compete with gravity so that only lighter magnetically sensitive particles 14A are attracted with the magnetic field having the first intensity. In some other applications, a plurality of types (e.g., 3 types) of magnetically sensitive particles can each have one or more different magnetic properties (such as permeability (or susceptibility), coercivity and/or remanence) such that they are more or less attracted by an external magnetic field.

A magnetic field source 28B can apply a magnetic field having a second intensity. This can cause magnetically sensitive particles 14A and 14B to come in contact with a surface of the container 142 as shown in FIG. 15C. The magnetic field applied by the magnetic field source 28C is not sufficiently strong to bring the magnetically sensitive particles 14C in contact with the container 142. The applied magnetic field can compete with gravity so that only magnetically sensitive particles 14A and 14B are attracted with the magnetic field having the second intensity.

Using metal contacts 144A and 144B, a measurement circuit can generate a case conductance measurement. A case conductance measurement corresponding to FIG. 15B indicates a magnetic field having a lower intensity than a case conductance measurement corresponding to FIG. 15C. It will be understood that fields with yet higher intensities beyond a different threshold can additionally attract the more massive particles 14C. While not shown, more than two metal contacts can be employed at different locations across the container 142. The apparatus can be calibrated for different magnetic field intensities to be indicated by different conductance measurements.

In some embodiments, systems disclosed herein can perform zero-power detection of exposure to a high magnetic field or magnetic field interference. With zero-power detection, a device does not need power to be applied during exposure to the external field in order to detect the magnetic field. Rather, power can be applied at a later stage while interrogating the system to take a measurement of the state of the system (or an external optical detection system can be used to detect clusters/movement of particles), but the system can maintain its status from the prior exposure without power until the later interrogation.

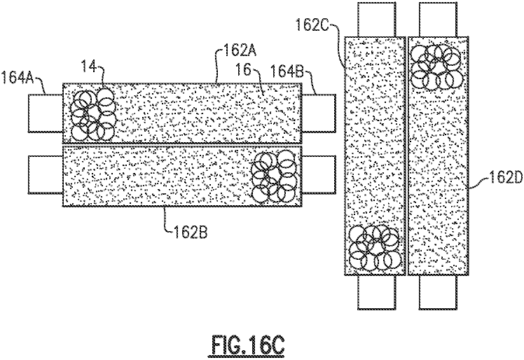

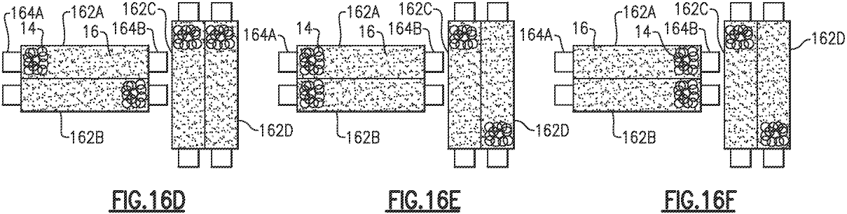

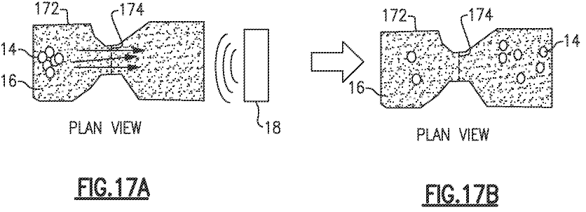

FIGS. 16A to 16F illustrate enclosures with particles that can be used for zero-power detection according to an embodiment. FIG. 16A illustrates an example enclosure 162 with biasing magnets 164A and 164B on opposing ends. The enclosure 162 is a sealed enclosure containing fluid 16 and magnetically sensitive particles 14 in the fluid 16. The enclosure 162 is pre-loaded with the magnetically sensitive particles 14 in an initial position as shown in FIG. 16A. In the illustrated initial position, the magnetically sensitive particles 14 are positioned at one end of the enclosure 162 by the biasing magnet 164A. The biasing magnet 164A can attract the magnetically sensitive particles to the initial position. If undisturbed, the magnetically sensitive particles 14 can stay in the initial position. Zero-power detection techniques can be applied to non-magnetically sensitive particles in magnetically sensitive fluids in certain applications.

FIG. 16B illustrates the magnetically sensitive particles 14 after a large magnet 165 (representative of any source of external magnetic field) causes the magnetically sensitive particles 14 to move from one end of the enclosure 162 to an opposite end of the enclosure. The large magnet 165 applies a larger magnetic field than the biasing magnets 164A and 164B. The biasing magnet 164B can retain the magnetically sensitive particles 14 in the position shown in FIG. 16B until a sufficiently large magnetic field moves the magnetically sensitive particles 14. Accordingly, the magnetically sensitive particles 14 can remain in the position shown in FIG. 16B after the large magnet 165 no longer applies a strong magnetic field. Power need not be applied at the time of the exposure for measurement. Rather, power can be later applied for measurement, even in the absence of the field, because the system maintains the status from the exposure without power.

A plurality of enclosures 162 can together be used to determine exposure to a magnetic field in a direction in space. For example, 4 enclosures 162 positioned relatively close to each other with a proper initial state of magnetically sensitive particles can record and store an indication of exposure to a relatively large magnetic field in a direction in an xy-plane. As another example, 6 enclosures 162 can be used to detect a magnetic field in the xyz-space. The shape and size of each enclosure and the particle size, shape, construction and fluid or gel type within the enclosure can be selected or modified depending on the specifications of a particular application.

FIG. 16C illustrates 4 enclosures 162A, 162B, 162C, 164D each including magnetically sensitive particles 14 in fluid 16 in an initial position according to an embodiment. The enclosures 162A, 162B, 162C, 164D can together be used to detect a magnetic field in a direction in an xy-plane. In the initial position, two enclosures are oriented along a direction with magnetically sensitive particles starting at opposing ends of the enclosures. Enclosures 162A and 162B are oriented along a first direction with magnetically sensitive particles 14 positioned at opposite ends. Enclosures 162C and 162D are oriented along a second direction with magnetically sensitive particles 14 positioned at opposite ends. As illustrated, the first and second directions are orthogonal. Each of the enclosures 162A, 162B, 162C, 164D can have integrated biasing magnets 164A and 164B and contain magnetically sensitive particles 14 and fluid 16. Reference numbers of these elements are included for the enclosure 162A and omitted for the other enclosures in FIGS. 16C, 16D, 16E, and 16F.

FIG. 16D illustrates the 4 enclosures 162A, 162B, 162C, 164D from FIG. 16C after exposure to a magnetic field. The magnetically sensitive particles 14 in enclosure 162C have moved from the initial position shown in FIG. 16C. This indicates exposure to a magnetic field from the direction where the magnetically sensitive particles 14 have moved to in the enclosure 162C. The positions of the magnetically sensitive particles 14 in the enclosures 162C and 162D shown in FIG. 16D together indicate a direction from which a magnetic field was applied. Any suitable detection technique can be used to determine positions of the magnetically sensitive particles 14 in the enclosures 162A, 162B, 162C, and 162D. A measurement circuit can output an indication of the applied magnetic field based on the detected positions of the magnetically sensitive particles in enclosures 162A, 162B, 162C, and 162D.

FIG. 16E illustrates the 4 enclosures 162A, 162B, 162C, 164D from FIG. 16C after exposure to a magnetic field from a different direction than in FIG. 16D. The magnetically sensitive particles 14 in enclosure 162B have moved from the initial position shown in FIG. 16C. This indicates exposure to a magnetic field from the direction where the magnetically sensitive particles 14 have moved to in the enclosure 162B. The positions of the magnetically sensitive particles 14 in the enclosures 162A and 162B shown in FIG. 16E together indicate the direction from which a magnetic field was applied.

FIG. 16F illustrates the 4 enclosures 162A, 162B, 162C, 164D from FIG. 16E after exposure to magnetic fields from an opposite direction than in FIG. 16E. Two magnetic fields have been applied to bring the magnetically sensitive particles 14 to the position in shown in FIG. 16E relative to the initial position in FIG. 16C. The magnetically sensitive particles 14 in enclosures 162A and 162B have moved from the position shown in FIG. 16E to an opposite end of these enclosures. This indicates exposure to a magnetic field from the direction where the magnetically sensitive particles 14 have moved to in the enclosures 162A and 162B. The positions of the magnetically sensitive particles 14 in the enclosures 162A and 162B shown in FIG. 16F together indicate the direction from which a magnetic field was applied. Applying magnetic fields in two opposite directions does not bring the magnetically sensitive particles in the enclosures 162A, 162B, 162C, 164D back to the initial position shown in FIG. 16C.

Cumulative magnetic field exposure can be determined based on positions of particles in a container. Systems can register if magnetic field exposure has exceeded a certain threshold in a passive way. Whether a device has been exposed to a relatively strong magnetic field can be detected even after the relatively strong magnetic field has been applied. Cumulative magnetic field exposure detection can be performed using magnetically sensitive particles in fluid or with non-magnetically sensitive particles within a magnetically sensitive fluid.

FIGS. 17A and 17B illustrate a system with cumulative magnetic field exposure detection according to an embodiment, which can be a measure of magnetic field “dose” or field strength integrated over time. The system includes an enclosure 172 including a flow restriction structure 174 that impedes passage of magnetically sensitive particles 14 therethrough. The flow restriction structure 174 can be semipermeable such that it is easier for particles to flow in one direction than in the opposite direction. The flow restriction structure 174 can be a membrane. The flow restriction structure 174 can be a filter or mesh or another suitable structure. In some embodiments, the flow restriction structure 174 can simply be a constriction of flow path cross section. The magnetically sensitive particles 14 can be in an initial position shown in FIG. 17A. A magnetic field source 18 applying a sufficiently strong magnetic field can cause at least some of the magnetically sensitive particles 14 to pass through the flow restriction structure 174. Then the magnetically sensitive particles 14 that have passed through the flow restriction structure 174 can be detected. Such detection can involve optical detection or any other suitable detection mechanism depending on the specifications of a particular application.

FIG. 17B illustrates a state where some of the magnetically sensitive particles 14 have passed through the flow restriction structure 174. Based on the positions of magnetically sensitive particles 14 that have passed through the flow restriction structure 174, a measurement circuit can generate an indication of a cumulative magnetic field exposure. The measurement can be generated after the sufficiently strong magnetic field is applied. The measurement can be generated while no magnetic field is being applied.

Magnetically sensitive particles can interact with microelectromechanical systems (MEMS) structures. MEMS structures can include magnetic material. Example MEMS structures include a see saw structure including magnetically sensitive material, a cantilever beam including magnetically sensitive material, a movable MEMS mass that includes magnetically sensitive material, a diaphragm or MEMS microphone including magnetic material, a MEMS gyroscope with magnetic material, and the like. MEMS structures can detect positions of magnetically sensitive materials in a container in certain applications. MEMS structures can apply a magnetic field to cause magnetically sensitive particles to move within a container in some applications. An external magnetic field source, a MEMS structure including magnetically sensitive material, and magnetically sensitive particles can interact. MEMS structures can be used for detecting positions of (1) magnetically sensitive particles within fluid and/or (2) non-magnetically sensitive particles within a magnetically sensitive fluid. For example, a MEMS structure can be part of an antenna such that the antenna changes depending on the intensity of the field and a transponder can detect the change in the antenna.

FIGS. 18, 19, and 20 illustrate example MEMS structures interacting with particles within a container according to embodiments. FIG. 18 illustrates a cantilever beam MEMS structure 182 and a container 12 with magnetically sensitive particles 14 in fluid 16. The cantilever beam MEMS structure 182 can include a magnetically sensitive layer 184 and be incorporated within silicon. The cantilever beam MEMS structure 182 can move in response to positions of magnetically sensitive particles 14 within a container 12. The position of the cantilever beam MEMS structure 182 can be used to sense an applied magnetic field. A measurement circuit connected to the cantilever beam MEMS structure 182 can generate an output signal indicative of the applied magnetic field.

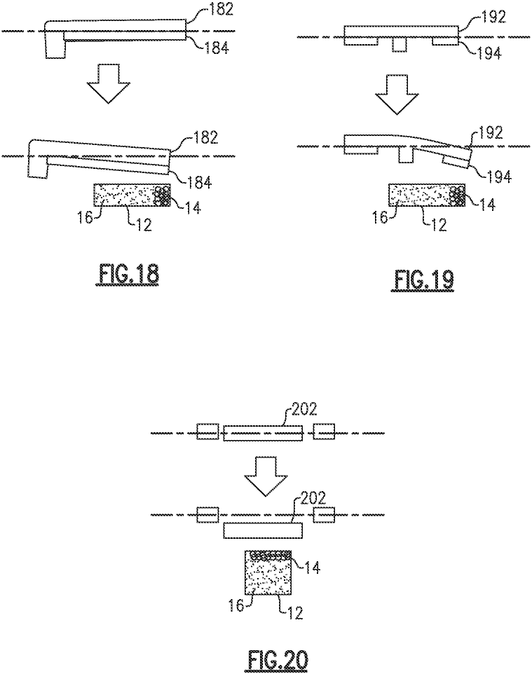

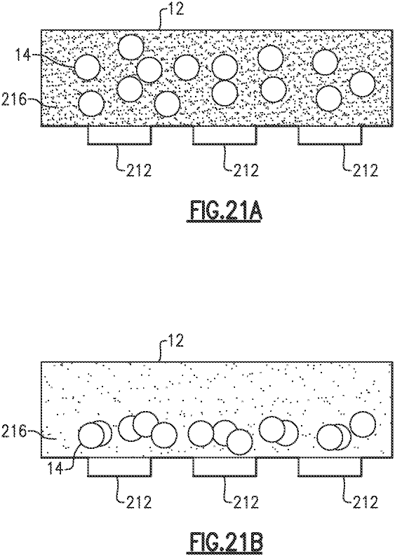

FIG. 19 illustrates a see saw MEMS structure 192 and a container 12 with magnetically sensitive particles 14 in fluid 16. The see saw MEMS structure 192 can incorporate magnetically sensitive material 194. The see saw MEMS structure 192 can move in response to positions of magnetically sensitive particles 14 within a container 12. The position of the see saw MEMS structure 192 can be used to sense an applied magnetic field. A measurement circuit connected to the see saw MEMS structure 192 can generate an output signal indicative of the applied magnetic field.

FIG. 20 illustrates a moveable mass MEMS structure 202 and a container 12 with magnetically sensitive particles 14 in fluid 16. The moveable mass MEMS structure 202 can incorporate magnetically sensitive material 204 and be tethered. The moveable mass MEMS structure 202 can move in response to positions of magnetically sensitive particles 14 within a container 12. The position of the moveable mass MEMS structure 202 can be used to sense an applied magnetic field. A measurement circuit connected to the moveable mass MEMS structure 202 can generate an output signal indicative of the applied magnetic field.

Magnetic sensors can be integrated with a container to sense positions of magnetically sensitive particles. Examples of such magnetic sensors include magnetoresistive sensors (for example, anisotropic magnetoresistance sensors, giant magnetoresistance sensors, or tunnel magnetoresistance sensors), fluxgate sensors, Hall effect sensors, search-coil sensors, giant magnetic impedance (GMI) sensors, and the like.

FIGS. 21A and 21B illustrate a container 12 with integrated magnetic sensors 212 according to an embodiment. The magnetic sensors 212 can be an array of magnetic sensors, such as a one dimensional array, a two dimensional array or a three dimensional array. As illustrated, the magnetic sensors 212 are positioned on an outer surface of the container 12. The container 12 includes a material 216 and particles 14. The particles 14 can be electrically conductive. The magnetic sensors 212 can sense positions of the particles 14 within the container. Depending on the magnetic material used in a particular application, a biasing field can be present for particle detection.

The material 216 can be a gel or fluid with different physical states at different temperatures. For example, the material 216 can be solid at room temperature and liquid at a higher temperature. At a higher temperature, the magnetically sensitive particles 14 can move in the material 216. For instance, wax, coconut oil, or fat are example materials that are solid at room temperature and liquid at higher temperatures. The material 216 can be used in accordance with any suitable principles and advantages of any of the magnetic field measurement systems disclosed herein. For example, the material 216 can be used with MEMS based sensors, capacitive sensors, optical sensors, case conductance measurement, zero-power detection, cumulative magnetic field exposure, or the like.

FIG. 21B illustrates a state where the material 216 is at a higher temperature than in FIG. 21A and the magnetically sensitive particles 14 have a higher mobility in the material 216 than in FIG. 21A. A magnetic field can be applied to move the magnetically sensitive particles 14 to the positions shown in FIG. 21B. The magnetic sensors 212 can detect the positions of the magnetically sensitive particles 14. A measurement circuit connected to the magnetic sensors 212 can output an indication of the applied magnetic field.

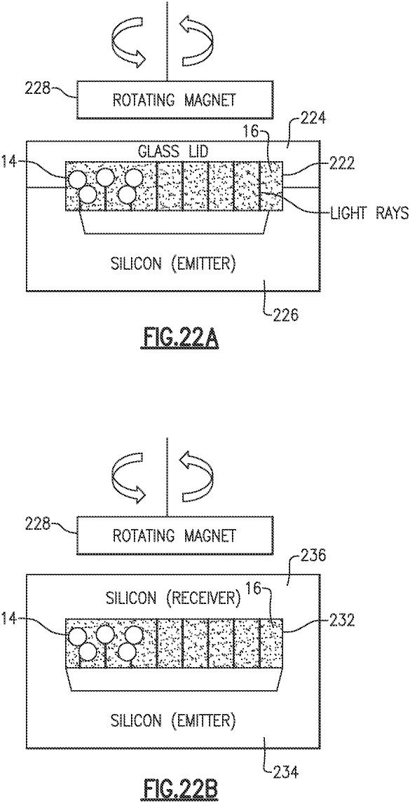

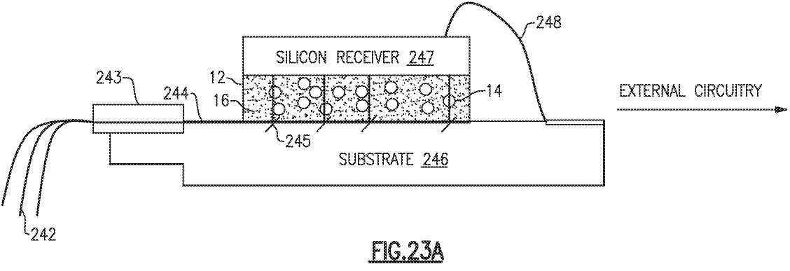

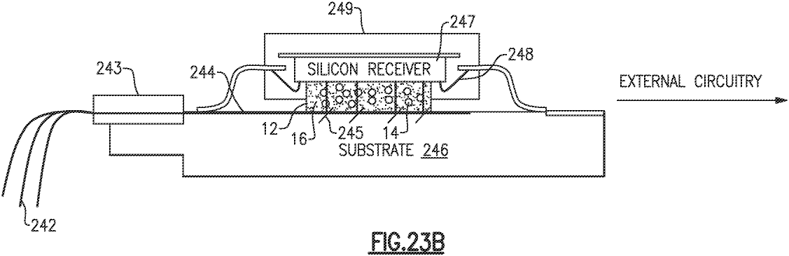

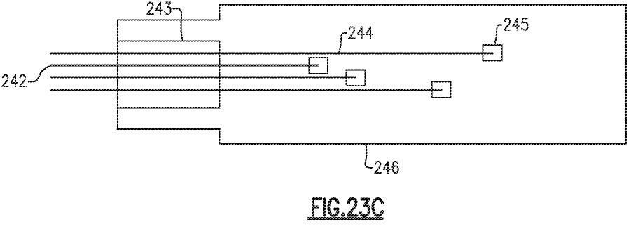

Positions of particles can also be detected optically. As a magnet rotates, particles within fluid can move with the rotation of the magnet and affect light transmission patterns inside the enclosure. With optics, rotation of the magnetic field can be determined. Optical detection can detect displacement and/or position of magnetically sensitive particles based on any suitable movement of a magnetic body or other magnetic field source. Example movements include rotation as discussed with reference to FIGS. 22 and 23 and linear motion. Optical detection is also applicable to stationary magnets or magnetic field sources. Optical detection can be a power efficient and relatively fast method of detecting magnetically sensitive particles. Example embodiments with optical detection are shown in FIGS. 22 and 23. Optical detection can be used for detecting positions of (1) magnetically sensitive particles within fluid and/or (2) non-magnetically sensitive particles within a magnetically sensitive fluid.

FIG. 22A illustrates a container 222 with magnetically sensitive particles 14 with optical detection. The container 222 includes a glass lid 224. A silicon emitter 226 integrated with the container 222 can emit light to the container 222. A rotating magnet 228 can cause the magnetically sensitive particles 14 to move. As the magnetically sensitive particles 14 move within fluid 16, detection of the light rays can change. For example, the magnetically sensitive particles 14 can block or otherwise adjust the path of light emitted from the emitter 226. The change in distance of the light rays can be detected with an optical detector (not illustrated) that is positioned over the glass lid 224 and used to calculate where the magnetically sensitive particles 14 have moved. The shape, size, enclosure construction and constituent materials (including fluid, gel, particles etc.), and location of an optical detector and emitter and how these are incorporated within the system can be modified and optimized depending on the specifications of the application. The principle of operation of the system can remain the same where the particles within the enclosure respond to a magnetic stimulus and through optical means (where an optically clear medium is incorporated within the system that facilitates detection of particles inferring an intensity, strength, direction or position of a magnetic field).

FIG. 22B illustrates a container 232 with particles 14 with integrated optical detection. The container 232 includes an integrated emitter 234 and an integrated receiver 236. The emitter 234 and the receiver 236 can each include silicon or another suitable semiconductor material. The material components of the construction can also be selected based on the ability to permit or prohibit light of certain wavelengths to pass through. For example, light in the infrared spectrum can pass through silicon. The selection, shape, size, and/pr construction of the constituent parts of the system and how these are incorporated within the system can be modified and optimized depending on the specifications of the application. The position of the magnetically sensitive particles 14 can be detected based on the light rays emitted by the emitter 234 and received by the receiver 236. The light rays can have any suitable wavelength for detection. For example, the light rays can be infrared rays. The positions of the magnetically sensitive particles 14 are indicative of rotation of the magnetic field cause by the rotating magnet 228 in FIG. 22B. More generally, optical detection can determine positions of particles moved in response to a magnetic field. In some instances, light sensitive metal pads can be included on a light receiver.

FIGS. 23A and 23B are schematic cross sectional or side views of optical measurement systems according to embodiments. The optical measurement systems can include fiber optic cables/sources 242, an optical edge coupler 243, waveguides 244, an angled gradient 245, particles 14 within a container 12 on a substrate 246, a silicon receiver 247, and an electrical path 248 (e.g., including a wire bond and/or any other suitable connections) to external circuitry. A packaging structure 249 can enclose the silicon receiver 247 and at least part of the container 12, for example, as shown in FIG. 23B. The packaging structure 249 can have an opening through which a portion of the container 12 is exposed.

FIG. 23C is a schematic view of a portion of the optical systems of FIGS. 23A and 23B. By providing light sources at multiple different positions through the container 12, and multiple light detectors (e.g., a light sensitive array) at the opposite side of the container 12, changes in positions of the particles 14 can be detected.

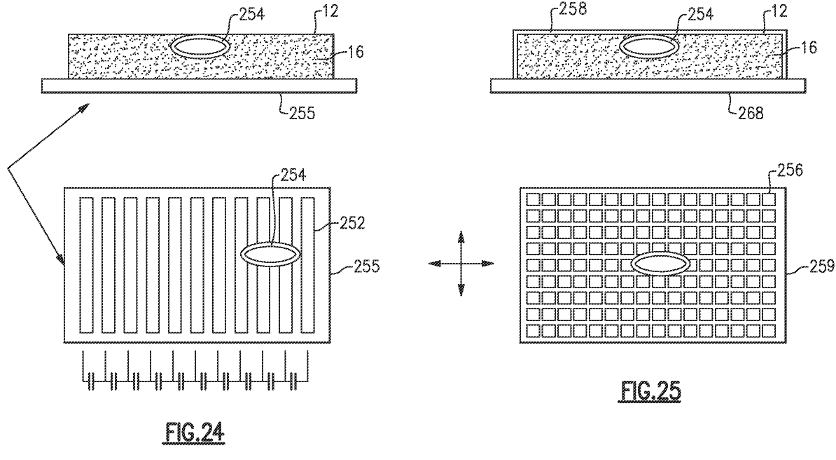

The position of one or more particles can be detected with capacitive sensing. Mutual capacitance can be measured to detect position of one or more particles in fluid within a container. In some instances, mutual capacitance can be continuously measured. Velocity can be determined by differentiating the continuous measurements once. Acceleration can be determined by differentiating the continuous measurements twice. Velocity and/or acceleration can be measured based on any suitable continuous position measurements (e.g., continuous optical measurements, etc.). A capacitive sensor, such as a complementary metal oxide semiconductor capacitive sensor, can be used to detect one or more magnetically sensitive particles. FIGS. 24 and 25 illustrate embodiments of detecting position of a magnetically sensitive particle with capacitive sensing.

FIG. 24 illustrates a capacitive sensor 252 integrated with a container 12 that includes a particle 254 within fluid 16. The particle 254 can be magnetically sensitive. The particle 254 can be a bead with a conductive coating. The container 12 and the capacitive sensor 252 can be integrated with wafer level chip scale packaging. The capacitive sensor 252 can be formed in a top metal layer of an integrated circuit 255, or can be a stand-alone device fabricated with packaging technology (e.g., sputtered, plated, screen printed, etched, etc.) and subsequently stacked. The different parts of the system can be heterogeneously integrated and incorporate chiplets and other components and/or functional parts depending on the specifications of a particular application. The capacitive sensor 252 can detect a one-dimensional position of the particle 254 based on a mutual capacitance measurement. The capacitive sensor 252 can include a one-dimensional array of capacitive sensing elements. A measurement circuit of the integrated circuit 255 can output an indication of an applied magnetic field based on the measured position.

FIG. 25 illustrate a capacitive sensor 256 integrated with a container 12 that includes a particle 254 within fluid 16. An electrical shield 258 can be positioned over the container 12. The capacitive sensor 256 can detect a two-dimensional position of the particle 254 based on a mutual capacitance measurement. The capacitive sensor 256 can include a two-dimensional array of capacitive sensing elements. The capacitive sensor 256 can be formed in a top metal layer of an integrated circuit 259. Alternatively, the capacitive sensor 256 can be a stand-alone device fabricated with packaging technology. A measurement circuit can output an indication of an applied magnetic field based on the measured position. One or more of the selection, shape, size and construction of the constituent parts of the system and how these are incorporated within the system can be modified and optimized depending on the specifications of a particular application.

### Comparative Measurements

Multiple measurements can be generated based on positions of particles within one or more compartments. At least some of the particles can move in response to an external stimulus, such as a magnetic field (e.g., one or more of intensity, direction, strength, etc.) or force applied to a compartment. A comparative measurement can be provided based on comparing at least the two different measurements, where the two measurements are associated with two or more types of particles and/or two or more compartments or enclosures. The comparative measurement can provide increased sensitivity relative to a single measurement.

Aspects of this disclosure relate to generating a comparative measurement based on multiple measurements associated with particles in one or more compartments. The particles can move in response to an external stimulus, such as an applied magnetic field or an applied force. The particles can be magnetically sensitive in certain applications. The multiple measurements can be associated with different types of particles. Alternatively or additionally, the multiple measurements can be associated with different compartments. In some instances, different compartments include different respective types of particles, such as particles with different sizes, masses, densities, sensitivities to an external stimulus, the like, or any suitable combination thereof. Alternatively or additionally, particles in different compartments can be in different fluids. In the different fluids, particles can have different mobilities. In some applications, the multiple measurements can be associated with a plurality of types of particles within a single compartment. The one or more compartments can include container(s), sealed enclosure(s), fluid channel(s), or the like. As disclosed herein, there are many different constituent parts that can deliver a change in resultant sensitivities depending on the specifications of the application.

Measurement sensitivity and/or accuracy can be increased by the multiple measurements associated with different particles and/or compartments. For example, with different types of particles in different compartments, each compartment can detect if a parameter (e.g., magnetic field, temperature, or force) is above or below a respective threshold value. With multiple compartments, the parameter can be determined within a range between thresholds associated with different compartments. Such a range is more accurate than detecting that the parameter is either below or above a threshold value. As another example, different types of particles with different respective sensitivities to an external stimulus can enable finer detection of an external stimulus based on the movement of the different types of particles.

With multiple compartments including particles, the presence and/or movement of an external stimulus (e.g., a magnetic field) can be localized. For example, sensing particle movement in a particular compartment and not other compartment(s) can indicate a location of the external stimulus.

A system can include a first compartment containing one or more first particles and a second compartment containing one or more second particles. At least some of the one or more first particles can move in response to an external stimulus. A measurement circuit can generate a measurement based on comparing a first measurement associated with position of the one or more first particles and a second measurement associated with position of the one or more second particles. In certain applications, such a system can detect that the one or more first particles have moved and a lack of movement of the one or more second particles. This can indicate that a parameter is within a range where the one or more first particles move and the one of more second particles do not move. The first and second compartments can include different types of particles. The first and second compartments can include fluids or medium materials with different properties.

A system can include a compartment containing at least two types of particles and a measurement circuit. The measurement circuit can generate a measurement based on comparing a first measurement and a second measurement. The first measurement is associated with positions of the at least two types of particles, and the second measurement is associated with positions of at least some particles of the two types of particles moving in response to an external stimulus relative to the positions associated with the first measurement.

With comparative measurements, any suitable measurement techniques can be used, such as any of the measurement techniques discussed above. For example, the measurements can be magnetic field measurements in accordance with any suitable principles and advantages discussed with reference to FIGS. 14A to 25. The measurements can be case conductance measurements, zero power magnetic field detection measurements, cumulative magnetic field exposure measurements, measurements using microelectromechanical systems, magnetic sensor measurements, magnetic sensor array measurements, measurements of movement of particles in phase change material, optical detection measurements (e.g., using an optical sensor or based on detection with a naked eye), capacitive measurements, the like, or any suitable combination thereof. The measurements can be temperature sensing measurements related to movement of particles in a medium material where the particles have a mobility in the medium material that changes with temperature. Such measurements can be implemented in accordance with any suitable principles and advantages disclosed in U.S. Pat. Application No. 18/053,523, filed Nov. 8, 2022, the technical disclosure of which is herein incorporated by reference in its entirety and for all purposes. The measurements can be of force applied to compartment(s).

The particles within a compartment can include any suitable particles disclosed herein. The particles can be magnetically sensitive. The particles can alternatively or additionally be electrically conductive. In certain applications, particles within different compartments can have different properties, such as one or more of size, density, mass, shape, or sensitivity to an external stimulus. Particles can be constructed to have specific shapes to enable movement within the enclosure in a desired way. A system can be further enhanced and/or optimized by the properties of the fluid/material in which the particles are contained (e.g., viscosity). Particles can be patterned with sensitive material and/or coated with specific thicknesses or materials that can affect the sensitivity/response for a particular application. For example, if a quick response time is desired, large particles in a low viscosity fluid could be used. On the other hand, if a slower (e.g., cumulative) exposure is being measured, a different shaped particle in a more viscous fluid can be used. Different shape/particle construction can be applied to enhance and/or optimize the sensitivity desired for a particular application.

The particles can be included in any suitable fluid, medium material, or film within a compartment. The particles can be within any suitable fluid disclosed herein. The particles can be included in any suitable medium material or phase change material disclosed herein and/or disclosed in U.S. Pat. Application No. 18/053,523. The particles can be embedded within a film, for example, as discussed above.

A compartment can be a container, a sealed enclosure, a channel, or the like. A compartment can be implemented in accordance with any suitable principles and advantages of the containers discussed above. A compartment can be implemented in accordance with any suitable principles and advantages of the channels disclosed in in U.S. Pat. Application No. 18/17,0765, filed Feb. 17, 2023, the technical disclosure of which is herein incorporated by reference in its entirety and for all purposes. A compartment can retain particles and/or fluid in certain applications. A compartment can allow fluid and/or particles to flow therethrough in some applications.

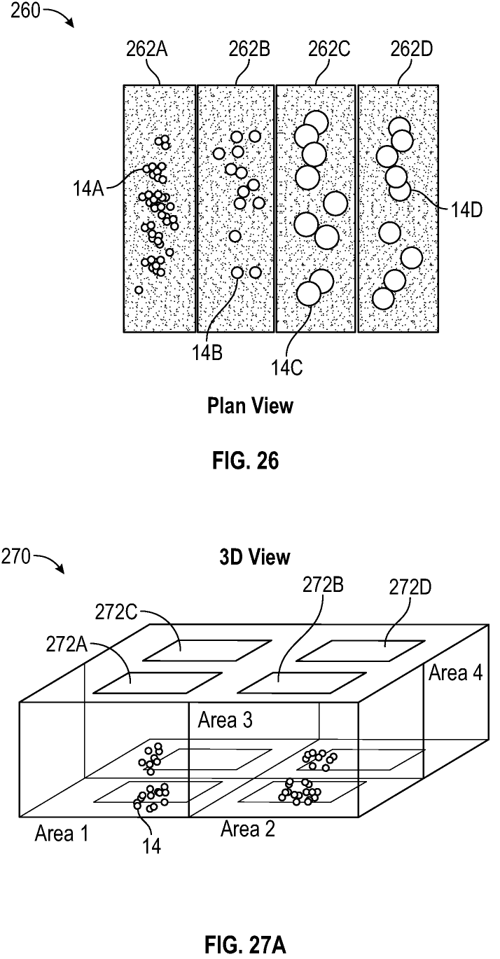

FIG. 26 illustrates a plan view of a system 260 with a plurality of compartments that include particles according to an embodiment. The system 260 includes a plurality of compartments 262A, 262B, 262C, and 262D that include respective particles 14A, 14B, 14C, and 14D within fluids. A comparative measurement can be generated using measurements associated with at least two individual compartments. The comparative measurement can be indicative of a magnetic field, a temperature, a force, or the like.

The compartments 262A, 262B, 262C, and 262D can have a shape and/or size tailored for a particular application. The compartments 262A, 262B, 262C, and 262D can be sealed enclosures in certain applications. The compartments 262A, 262B, 262C, and 262D can be fluid channels in some applications. Any suitable number of compartments can be used for a particular application. Also, the shape and/or size of each compartment can be modified and optimized depending on the specifications of the application.

Each compartment 262A, 262B, 262C, and 262D can include a different respective type of particle 14A, 14B, 14C, and 14D. The different particles 14A, 14B, 14C, and 14D have a different property that causes them to have a different sensitivity to an external stimulus. The different property can include particle size, particle thickness, particle mass, particle density, particle material, particle shape, particle mobility within a fluid, the like, or any suitable combination thereof. As illustrated in FIG. 26, the different particles 14A, 14B, 14C, and 14D have different sizes. This can cause the different particles 14A, 14B, 14C, and 14D to have a different respective sensitivity to an external stimulus. For example, the different particles 14A, 14B, 14C, and 14D can have a different respective sensitivity to an external magnetic field when the particles include magnetically sensitive material. The different particles 14A, 14B, 14C, and 14D can move a different amount in a respective compartment 262A, 262B, 262C, and 262D in response to the same stimulus. In some instances, one or more type of the different particles 14A, 14B, 14C, and 14D can move in response to a particular stimulus while one or more other types of the different particles 14A, 14B, 14C, and 14D do not move in response to the particular stimulus. For example, the particles 14A can move and the particles 14D can remain in the same positions in response to a relatively weak stimulus.

In certain applications, the different particles 14A, 14B, 14C, and 14D can each be within a same or similar fluid. Two or more different particles 14A, 14B, 14C, and 14D can be within different fluids that impact particle movement in some other applications. For example, the different fluids can have different viscosities under the same environmental conditions. As another example, the different fluids can be phase change materials that change phase at different respective temperatures. Phase change materials can be used such that particles within such phase change materials only move when temperature is above or below a threshold temperature.

A measurement circuit can generate a comparative measurement based on comparing measurements associated with at least two of the compartments 262A to 262D. The measurements associated with at least two of the compartments 262A to 262D can be generated sequentially. The measurements associated with at least two of the compartments 262A to 262D can be generated concurrently. The measurement circuit can generate measurements associated with individual compartments 262A to 262D. Comparing measurements associated with individual compartments can increase measurement sensitivity and/or accuracy. The measurement circuit can be implemented in accordance with any suitable principles and advantages of the measurement circuits disclosed herein. As one example, the measurement circuit can be implemented in accordance with any suitable principles and advantages of the measurement circuit 73 of FIG. 7.

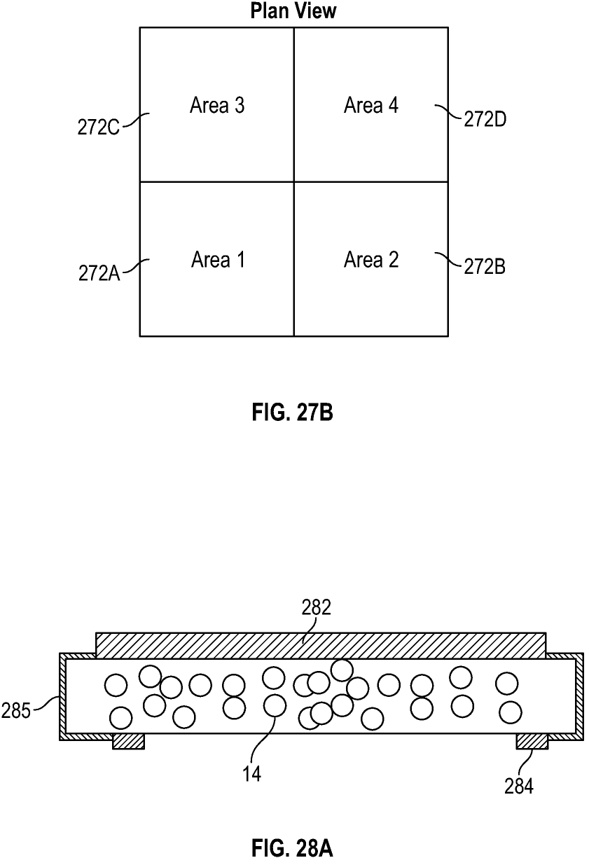

FIG. 27A is an isometric view of a system 270 with a plurality of compartments 272A, 272B, 272C, and 272D each including particles 14 according to an embodiment. FIG. 27B is a plan view of the system 270 that illustrates areas of the compartments 272A, 272B, 272C, and 272D. The compartments 272A, 272B, 272C, and 272D can be partitioned particle spaces. Each of the compartments 272A to 272D can be an isolated space in which particles 14 are free to move. The particles 14 can be within a fluid in each of the particle spaces. Movement of the particles 14 can be detected in one or more of the compartments 272A to 272D. In certain applications, the compartments 272A, 272B, 272C, and 272D can include the same type of particles 14.

The system 270 can include a plurality of relatively small particles spaces in the form of compartments 272A, 272B, 272C, and 272D. Particles in different particle spaces can be isolated from each other. Measurements can be generated associated with two or more individual compartments 272A, 272B, 272C, and 272D. A measurement can be generated associated with each of the compartments 272A, 272B, 272C, and 272D. The measurement can indicate that part of a chip or system is functional. Alternatively, the measurement can indicate that part of a chip or system may be damaged or otherwise unreliable. By comparing a plurality of measurements each associated with an individual compartment 272A, 272B, 272C, or 272D, a comparative measurement can be generated that is indicative of whether certain parts of a chip or system may have issues. This can bin part(s) of a chip or system instead of binning an entire chip or system. The comparative measurement can indicate a location of a problem.

In the system 270, a first side of each compartment 272A to 272D can include an electrical contact. The electrical contact can cover the entire first side of a compartment in certain applications. A second side of the compartment can include one or more electrically controllable pads, where the second side is opposite to the first side. With multiple connections, better reliability can be achieved.

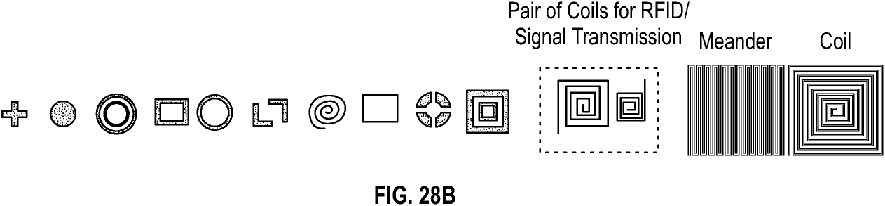

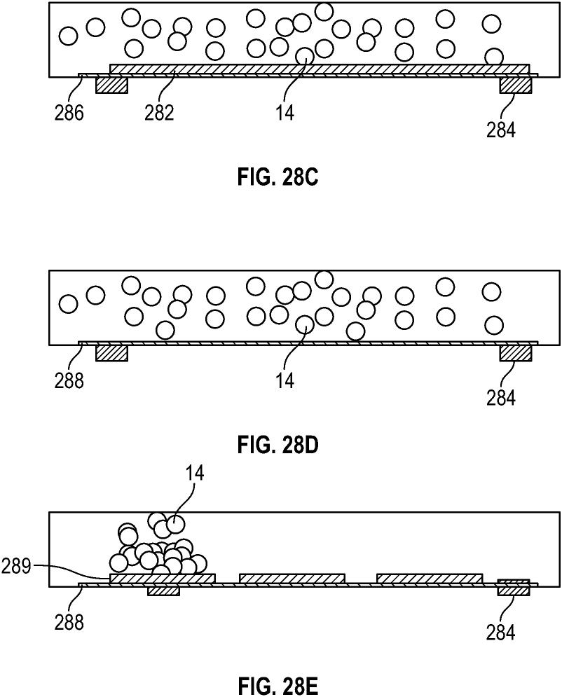

FIGS. 28A to 28E illustrate examples of compartments and integrated structures according to embodiments. An array of such compartments can be used for generating a comparative measurement. A comparative measurement can be generated using measurements associated with an individual compartment of a plurality of compartments in accordance with any suitable principles and advantages of FIGS. 28A to 28E. The compartments of FIGS. 28A and 28C to 28E can be sealed enclosures. Any suitable principles and advantages of these embodiments can be implemented together with each other and/or with other embodiments disclosed herein.

FIG. 28A illustrates a compartment according to an embodiment. The illustrated compartment includes particles 14 within fluid and an integrated magnetic structure 282. The particles 14 can be magnetically sensitive. The integrated magnetic structure 282 can be positioned on an outer surface of the compartment. The integrated magnetic structure 282 can generate a magnetic field. The integrated magnetic structure 282 can provide a bias. The integrated magnetic structure 282 can include a meandering conductor, two phase conductive paths, or any other suitable magnetic structure. The integrated magnetic structure 282 can generate a varying magnetic field. The compartment can include one or more contacts 284, such as bumps, terminations, or other electrical connections. The one or more contacts 284 can be on an active side of the compartment. One or more conductive traces 285 can connect the one or more contacts 284 to the integrated magnetic structure 282.

FIG. 28B illustrates example patterned magnetic structures. These magnetic structures can be formed by any suitable method, such as deposition. The magnetic structures can have any suitable shape or pattern for a particular application. The magnetic structure can include conductive material. The example magnetic structure can implement suitable integrated magnetic structure disclosed herein, such as the integrated magnetic structures 282 of FIG. 28A and/or FIG. 28C. Conductive structures that can create magnetic fields can be incorporated (e.g., RFID coils, meander structures, etc.) and modified depending on the specifications of the specific application.

FIG. 28C illustrates a compartment according to another embodiment. The compartment of FIG. 28C has an integrated magnetic structure at a different location and different electrical connections to electrical contacts than the compartment of FIG. 28A. As illustrated in FIG. 28C, the integrated magnetic structure 282 can be located within a compartment. An integrated magnetic structure 282 can be electrically connected to one or more electrical contacts 284 by way of a conductive trace 286 and a via 287 extending through a wall of the compartment.

A sensing structure can be included within a compartment. The sensing structure can include a conductive area that can come into physical contact with particles and generate a discernable electrical output.

FIG. 28D illustrates a compartment with a sensing structure according to an embodiment. In the compartment shown in FIG. 28D, a conductive sensing structure 288 can generate an electrical output when conductive particles 14 are in physical and/or electrical contact with the conductive sensing structure 288. The electrical output can indicate when particles 14 are clustered and/or concentrated and in physical and/or electrical contact with the conductive sensing structure 288. The conductive sensing structure 288 can be electrically connected to one or more electrical contacts 284 by way of one or more vias 287. The one or more electrical contacts 284 can be electrically connected to any suitable processing circuitry and/or ASIC. The processing circuitry and/or ASIC can include a measurement circuit. The measurement circuit can generate a comparative measurement based on measurements associated with individual compartments with sensing structures, such as the conductive sensing structure 288.

An integrated structure to concentrate particles and a sensing structure can be included within a compartment. The integrated structure can be a magnetic structure arranged to cluster and/or concentrate particles within the compartment. The sensing structure can sense the clustering and/or concentration of the particles.

FIG. 28E illustrates a compartment with an integrated clustering structure and a sensing structure according to an embodiment. In the compartment shown in FIG. 28E, a clustering structure 289 can cause the particles 14 to cluster at a particular area. This clustering can occur in response to an external stimulus. For example, the clustering structure 289 can be a magnetic structure that attracts the particles 14 and the particles 14 can be clustered at a particular location of the integrated clustering structure 289 in the presence of a certain magnetic stimulus. The conductive sensing structure 288 can generate an electrical output when conductive particles 14 are clustered at a particular location. The electrical output can be provided by way of one or more electrical contacts 284 to a measurement circuit to generate a comparative measurement.

An array of compartments containing particles can be used to generate a comparative measurement. The array can be located at an area of interest of a system for which the comparative measurement is generated. The compartments of the array can each include a separate enclosure that contains magnetically sensitive particles. The particles can be included within a fluid or gel within the individual compartments.

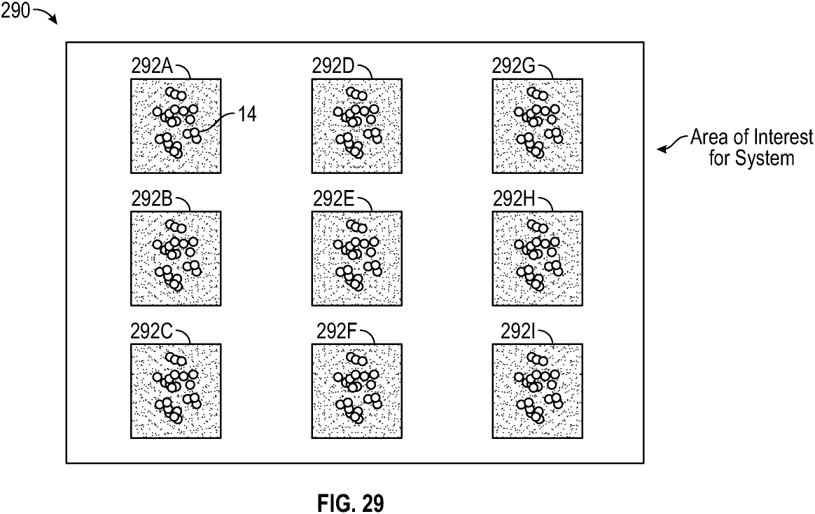

FIG. 29 illustrates an array 290 of compartments 292A to 292I that each include particles 14 according to an embodiment. In some applications, each compartment 292A to 292I includes the same or similar particles 14 within the same or similar fluid or gel. The array 290 can be used to localize a measurement. In certain instances, one or more compartments of an array can include a different type of particles (e.g., one or more of size, shape, construction, etc.). The different types of particles can be selected to sense particular ranges and/or magnitudes of stimuli. By sensing position and/or movement of different particle types in the presence of the same or similar stimulus, a more accurate comparative measurement can be generated. In some instances, one or more compartments of an array can include different types of fluid or medium material that contain particles. The different types of fluid or medium material can be selected to sense particular ranges and/or magnitudes of stimuli. By sensing position and/or movement of particles in different types of fluid or medium material in the presence of the same or similar stimulus, a more accurate comparative measurement can be generated.

An array of discrete compartments of particles can be arranged to sense certain directional fields, presences of magnetic bodies or fields, movement of magnetic fluids or other media depending on the application. In some instances, a plurality of arrays of compartments with particles can be implemented to generate different types of comparative measurements and/or to generate comparative measurements at different locations. The arrays and/or compartments can be next to one or more of channels, pipes, surfaces, integrated with modules, the like, or any suitable combination thereof. Also, the plurality of compartments can be located in non-orthogonal arrays (e.g., radial or random or at defined locations relative to the area being monitored) depending on the specifications of the application.

In certain applications, compartments can include particles within different medium materials. A comparative measurement can be generated based on measurements associated with different compartments, such as containers or sealed enclosures, with different respective medium materials. The comparative measurement can be indicative of temperature.

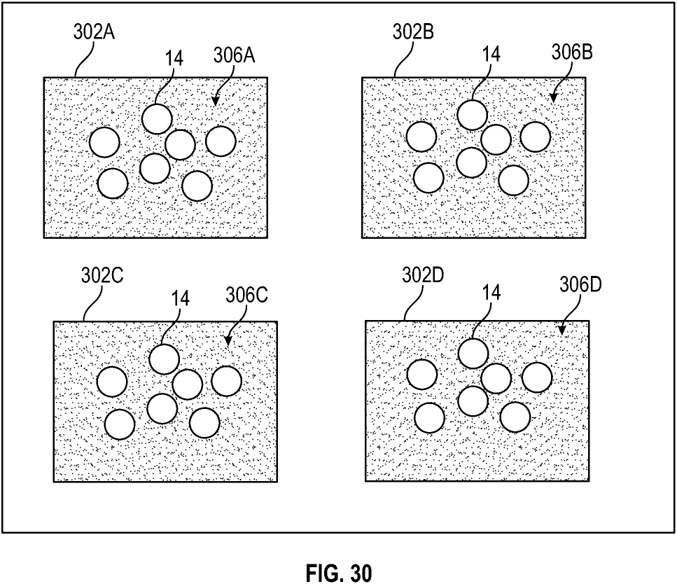

FIG. 30 illustrates a plurality of containers 302A, 302B, 302C, and 302D with particles 14 in different respective medium materials 306A, 306B, 306C, and 306D according to an embodiment. The containers 302A to 302D can be arranged in an array. The different medium materials 306A, 306B, 306C, and 306D can have different properties, such as different melting points, different vaporization temperatures, etc. The different containers 302A to 302D can be positioned sufficiently close to each other such that they experience a similar temperature.

Temperature can be detected based on movement or lack of movement of the particles in the containers 302A to 302D. For example, when movement of particles 14 is detected in containers 302A, 302B, and 302C with medium materials 306A, 306B, and 306C and no movement of particles 14 is detected in the container 302D with medium material 306D, this can indicate that temperature is in a range from (a) above the highest temperature that causes one of the medium materials 306A, 306B, and 306D to transition to a state in which particles 14 are mobile to (b) below the temperature at which the medium material 306D transitions to a state in which the particles 14 are mobile. Such temperature detection can be more accurate than detecting temperature based on movement of particles 14 in a single one of the containers 302A to 302D because such temperature can determine temperature to be within a range with both an upper bound and lower bound. A measurement circuit can process outputs of sensors associated with each of the containers 302A to 302D and output an indication of temperature. This structure can provide give an indication of the range of temperatures that the system is exposed to.

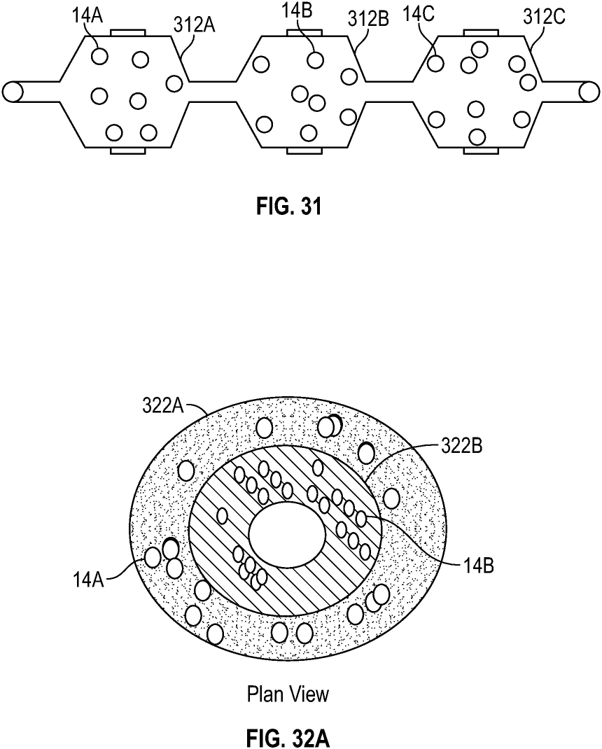

A system can include multiple compartments where each of the compartments includes particles of a different size. FIG. 31 illustrates a system that includes plurality of compartments 312A, 312B, and 312C with respective particles 14A, 14B, and 14C having different sizes according to an embodiment. Each of the compartments 312A, 312B, and 312C can include an integrated sensing structure and/or an integrated biasing structure. As illustrated in FIG. 31, the compartments 312A, 312B, and 312C can be connected to each other. The particles 14A, 14B, and 14C can be sized such that they are retained within respective compartments 312A, 312B, and 312C.

In certain embodiments, different compartments can be connected. A combination of different compartments with different particle sizes can facilitate a number of different uses. The different compartments can, for example, enable different agitating steps for processing and/or analyzing a fluid passing through a system. Such a system can include linked compartments with different sized particles enclosed. Each compartment can be constructed to manipulate and/or agitate the fluid in each chamber differently. Alternatively or additionally, different particle sizes in each compartment can enable different sensitivities and/or responses to the material moving through each connected compartment. Depending on the specifications of the application, each compartment can be constructed with different shapes and/or sizes and incorporate different sized particles (with different responsiveness to a stimulus). This can result in the fluid within each compartment being manipulated/agitated in a different manner. Each compartment can also incorporate one or more heating elements so that the fluid passing through the connected compartments can be treated or processed in a desired manner depending on the specifications of the application. This can be as part of an analytical process where an aspect or property of the fluid is being measured and/or recorded.

A plurality of compartments with different magnetic particle sizes can be used to construct an enhanced liquid chromatography system. Liquid chromatography is a technique used to separate and detect different ionic species in liquid samples (e.g. Cl-, Br-, I-, NO3-, etc.). Liquid chromatography can be used in a variety of applications (e.g., pharmaceutical and/or any industrial application in which an understanding of the ion composition of a sample is desired). In a liquid chromatography system that includes the compartments 312A, 312B, and 312C of FIG. 31, the liquid sample flows through a first compartment 321A or chamber that contains specifically constructed particles/beads. The different ions in the sample, which will pass through all of the connected compartments 312A, 312B, and 312C, have different degrees of interaction with such particles/beads so that the ions with least interaction with the particles/beads can leave the compartment first (into the next compartment). The ions with more interaction with the particles/beads can leave the compartment last. The particles/beads can be magnetically sensitive. At the end of a compartment there can be a sensor (e.g., a conductivity sensor) that can quantify the concentration of each ion type and/or other discernible properties of the resultant material in the last compartment. Different compartments with different size particles/beads may provide an enhanced sensitivity and/or resolution or ionic separation, etc. At the same time, electrodes can be included in each compartment to detect (e.g., electrochemically) different analytes in the sample as they get separated via interaction with the beads. Besides electrodes, other elements, such as one or more heaters, etc., can be included to further manipulate the sample as it passes through a compartment.

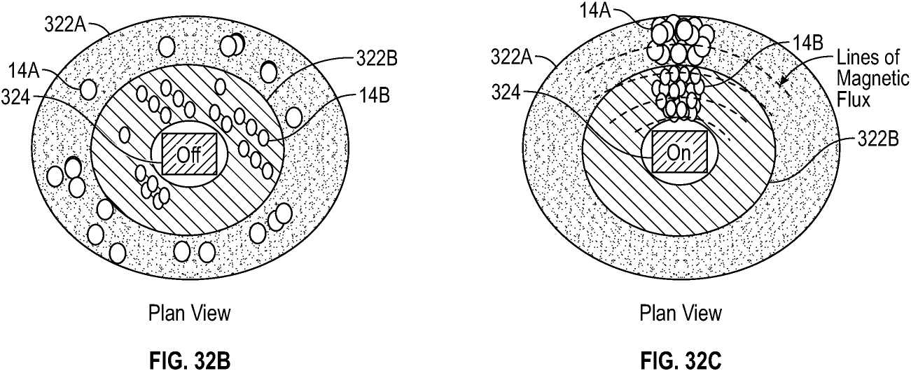

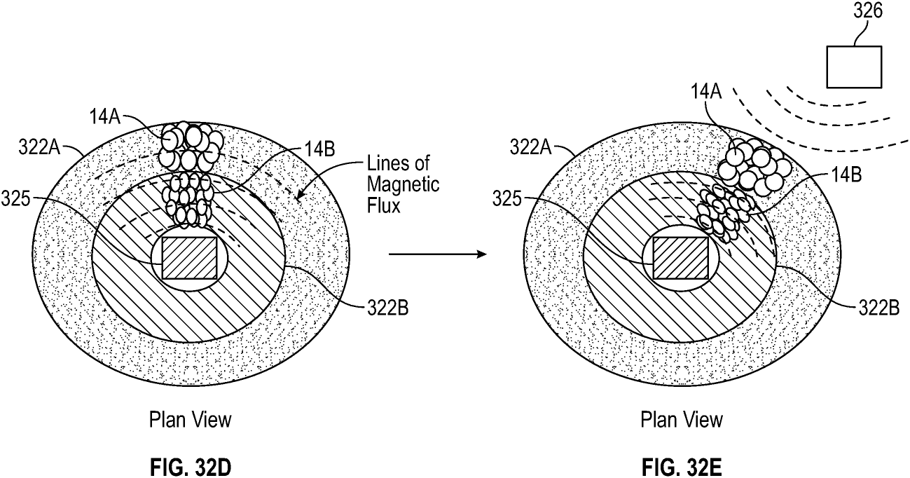

In certain applications, magnetically sensitive particles can be included within a plurality of fluid channels. An example embodiment of such fluid channels with be discussed with reference to FIGS. 32A to 32D. Different particle types having different properties can be included in different respective fluid channels. In response to a magnetic stimulus, at least some of the particles in the fluid channels can move. Movement and/or position of the particles can be sensed to determine a location, concentration, or other detectable signature to make a measurement based on the particles in the fluid channels. Multiple measurements can be compared to generate a comparative measurement.

FIG. 32A illustrates fluid channels 322A and 322B that include respective particles 14A and 14B according to an embodiment. The fluid channels 322A and 322B are example compartments that include particles for generating a comparative measurement. Increased measurement sensitivity can be achieved using different particles 14A and 14B in different fluid channels 332A and 332B. This construction can be used to detect the presence of a magnetic body outside the concentric structures and/or passing through the central opening. The shape, size, materials and/or construction of the channels can be modified and optimized depending on the specifications of the application.

In certain applications, the system of FIG. 32A can detect and/or react to a magnetic field passing through a center of the construction or outside the construction. As an example, the fluid channels 322A and 322B can be concentric tubes. A first fluid channel 322A is positioned about or around a second fluid channel 322B in FIG. 32A. As illustrated, the first fluid channel 322A can surround the second fluid channel 322B in plan view. The fluid channels 322A and 322B can be concentric. The fluid channels 322A and 322B can be sized and shaped for a particular application.

The fluid channel 322A can include magnetically sensitive particles 14A that have different sensitivity to a magnetic field that the magnetically sensitive particles 14B in the fluid channel 322B. For example, the different sizes can cause the particles 14A to have a different magnetic field sensitivity than the particles 14B due to their size, mass, ability to move within a compartment, the like, or any suitable combination thereof. The particles 14A and 14B can be selected depending on the system specifications and/or measurement sensitivity desired. With

The compartments 322A and 322B can include the same or similar fluids and/or materials. Alternatively, the particles 14A and 14B in respective compartments 322A and 322B can be included in different fluids and/or materials.

FIGS. 32B and 32C illustrate that a biasing structure 324 can be positioned about the fluid channels 322A and 322B. The fluid channels 322A and 322B can be positioned around the biasing structure 324, for example, as shown in FIGS. 32B and 32C. The biasing structure 324 can generate a magnetic field when turned on. In FIG. 32B, the biasing structure 324 is off and not generating a magnetic field. When the biasing structure 324 is off, the particles 14A and 14B can be in any suitable positions within the fluid channels 322A and 322B. In FIG. 32C, the biasing structure 324 is on and generating a magnetic field. When the biasing structure 324 is generating a magnetic field, the particles 14A and 14B can align relative to the magnetic field and/or lines of flux, for example, as shown in FIG. 32C. The biasing structure can enable the particle positions to be reset, where the particles are intentionally moved to a specific region before a sensing cycle is initiated.

In some applications, a biasing structure that includes a permanent magnet or other structure with fixed magnetic properties can be positioned about fluid channels. FIGS. 32D and 32E illustrate a biasing structure 325 be positioned about the fluid channels 322A and 322B, where the biasing structure 325 has fixed magnetic properties and generates a magnetic field.

At least some of the particles 14A and/or 14B can move in response to a magnetic stimulus from a magnetic field source 326. This movement can correspond to the change from the particle positions shown in FIG. 32D to the particle positions shown in FIG. 32E. As a magnetic field source 326 moves closer to the fluid channels 322A and 322B, the particles 14A and 14B can move and/or align in a way that (1) causes the particles to concentrate in a particular direction and/or concentration and/or (2) produces a discernible and/or detectable signature. FIG. 32E illustrates that particles can move in response to the magnetic field source 326 moving closer to the fluid channels 322A and 322B relative to FIG. 32D.

A measurement circuit can generate a comparative measurement based on comparing a first measurement associated with particle positions corresponding to FIG. 32D and a second measurement associated with particle positions corresponding to FIG. 32E. Both the first measurement and the second measurement can be associated with two different types of particles 14A and 14B that have different sensitivities to the magnetic stimulus provided by the magnetic field source 326. Such measurements can be performed sequentially. Comparing these measurements can increase measurement sensitivity and/or accuracy relative to a single measurement. In some applications, two measurements associated with two different sets of compartments with different particles can be performed. Such measurements can be performed sequentially or concurrently. In some applications, three or more measurements associated with three or more individual sets of compartments with different particles can be performed. The measurement circuit can be implemented in accordance with any suitable principles and advantages of the measurement circuits disclosed herein. As one example, the measurement circuit can be implemented in accordance with any suitable principles and advantages of the measurement circuit 73 of FIG. 7.

The biasing structure 324 of FIGS. 32B and 32C and the biasing structure 325 of FIGS. 32D and 32E are example biasing structure positioned about compartments that includes magnetically sensitive particles. Other biasing structures can be implemented in accordance with any suitable principles and advantages disclosed herein. For example, a meander shaped biasing structure can be positioned about one or more compartments. Such a meander shaped biasing structure can be above and below a compartment. A biasing structure can be combined with any suitable combination of features of the compartments disclosed herein.

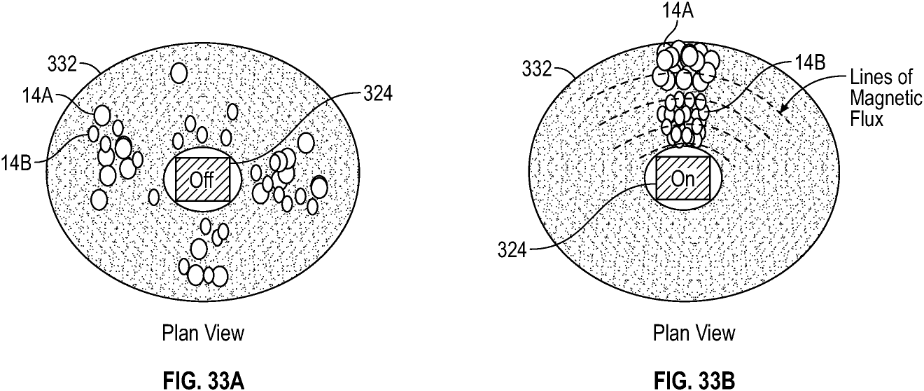

FIGS. 33A and 33B illustrate a fluid channel 332 with different types of particles 14A and 14B according to an embodiment. These figures illustrate that different types of particles can be included in a single compartment. A comparative measurement can be generated based on two or more measurements associated with the particles 14A and 14B in the fluid channel 332. The particles 14A and 14B can be magnetically sensitive particles. Such magnetically sensitive particles can have different magnetic field sensitivity and due to their different properties, such as one or more of size, mass, ability to move within the fluid channel 332, or the like. Comparing a plurality of measurements associated each with at least two types of particles 14A and 14B can increase measurement sensitivity (1) relative to two measurements associated with a single type of particle and (2) relative to a single measurement associated with the at least two types of particles.

In FIG. 33A, the biasing structure 324 is on. When the biasing structure 324 is on, the particles 14A and 14B can align along lines of magnetic flux. An external magnetic field can be applied to the compartment 332 to cause at least some of the particles 14A and 14B to move relative to the position shown in FIG. 33B. This can be used as a reset function. Two measurements associated with the particles 14A and 14B where at least some of these particles are in different positions can be compared to generate a comparative measurement. In some applications, two measurements associated with different fluid compartments 332 each including particles 14A and 14B can be compared to generate a comparative measurement.

### Conclusion

In the embodiments described above, apparatus, systems, and methods for detecting an applied magnetic field based on the position of ate least one particle within a container are described in connection with particular embodiments. It will be understood, however, that the principles and advantages of the embodiments can be used for any other systems, apparatus, or methods with a need for magnetic field detection.

The principles and advantages described herein can be implemented in various apparatuses. Examples of such apparatuses can include, but are not limited to, consumer electronic products, parts of the consumer electronic products, electronic test equipment, vehicular electronic products, industrial electronic products, etc. Examples of parts of consumer electronic products can include clocking circuits, analog-to-digital converts, amplifiers, rectifiers, programmable filters, attenuators, variable frequency circuits, etc. Examples of the electronic devices can include memory chips, memory modules, circuits of optical networks or other communication networks, and disk driver circuits. Electronic products can include, but are not limited to, wireless devices, a mobile phone (for example, a smart phone), cellular base stations, a telephone, a television, a computer monitor, a computer, a hand-held computer, a tablet computer, a laptop computer, a wearable computing device, a vehicular electronics system, a microwave, a refrigerator, a stereo system, a digital video recorder (DVR), a digital music players, a radio, a camera, a digital camera, a portable memory chip, a washer, a dryer, a washer/dryer, a copier, a facsimile machine, a scanner, a wrist watch, a smart watch, a clock, a wearable health monitoring device, etc. Further, apparatuses can include unfinished products.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The words “coupled” or “connected”, as generally used herein, refer to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values provided herein are intended to include similar values within a measurement error.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states.

The teachings of the inventions provided herein can be applied to other systems, not necessarily the systems described above. The elements and acts of the various embodiments described above can be combined to provide further embodiments. The acts of the methods discussed herein can be performed in any order as appropriate. Moreover, the acts of the methods discussed herein can be performed serially or in parallel, as appropriate.

While certain embodiments of the inventions have been described, these embodiments have been presented by way of example only, and are not intended to limit the scope of the disclosure. Indeed, the novel methods and systems described herein may be embodied in a variety of other forms. Furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure. Accordingly, the scope of the present inventions is defined by reference to the claims.

What is claimed is:

1. A method comprising:
generating a first measurement and a second measurement based on positions of particles within one or more compartments, wherein at least some of the particles are configured to move in response to an external stimulus; and
providing a comparative measurement based on comparing at least the first measurement with the second measurement, wherein the first and second measurements are associated with two or more types of particles and/or two or more compartments.

2. The method of claim 1, wherein the external stimulus is a magnetic field, and the comparative measurement is indicative of the magnetic field.

3. The method of claim 1, wherein the comparative measurement is indicative of a temperature being within a temperature range.

4. The method of claim 1, wherein the comparative measurement is indicative of a force applied to the one or more compartments.

5. The method of claim 1, wherein the particles are magnetically sensitive and in at least one fluid.

6. The method of claim 1, wherein the first and second measurements are associated with the two or more types of particles.

7. The method of claim 6, wherein the two or more types of particles have different magnetic sensitivities.

8. The method of claim 6, wherein the two or more types of particles have at least one of different sizes or different shapes.

9. The method of claim 1, further comprising resetting the positions of particles before generating the first measurement.

10. The method of claim 1, wherein the first and second measurements are associated with the two or more compartments.

11. The method of claim 10, wherein the two or more compartments comprise different fluid channels.

12. The method of claim 10, wherein the two or more compartments comprise different sealed enclosures.

13. The method of claim 10, wherein the two or more compartments comprise different medium materials in different respective compartments of the two or more compartments, and the different medium materials change viscosity in response to a change in temperature.

14. The method of claim 10, wherein the particles are in different fluids in each of the two or more compartments.

15. The method of claim 1, wherein the one or more compartments comprise an integrated sensing structure.

16. A method comprising:
generating a first measurement and a second measurement based on positions of magnetically sensitive particles within compartments; and
providing a comparative measurement based on comparing at least the first measurement with the second measurement, wherein the first and second measurements are associated with two or more of the compartments.

17. A system comprising:
a first compartment containing one or more first particles, wherein the one or more first particles are configured to move in response to an external stimulus;
a second compartment containing one or more second particles; and
a measurement circuit configured to generate a measurement based on comparing a first measurement associated with position of the one or more first particles and a second measurement associated with position of the one or more second particles.

18. The system of claim 17, wherein the external stimulus is a magnetic field, and the measurement is indicative of the magnetic field.

19. The system of claim 17, wherein the measurement is indicative of a temperature being within a temperature range.

20. The system of claim 17, wherein the one or more first particles are in a first fluid and the one or more second particles are in a second fluid, and the first fluid is a different type of fluid than the second fluid.
